(19) United States
(12) Patent Application Publication
(10) Pub. No.: US 2025/0386596 A1
(43) Pub. Date: Dec. 18, 2025

(54) SEMICONDUCTOR DEVICE

(71) Applicant: Samsung Electronics Co., Ltd., Suwon-si (KR)

(72) Inventors: Jaeho JEON, Suwon-si (KR); Donghoon HWANG, Suwon-si (KR); Seongkwang KIM, Suwon-si (KR); Byungho MOON, Suwon-si (KR); Wonchang LEE, Suwon-si (KR); Minwoo KIM, Suwon-si (KR)

(73) Assignee: Samsung Electronics Co., Ltd., Suwon-si, Gyeonggi-do (KR)

(21) Appl. No.: 18/978,499

(22) Filed: Dec. 12, 2024

(30) Foreign Application Priority Data
Jun. 13, 2024 (KR) 10-2024-0077251

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

A semiconductor device may include a lower active pattern extending in a first direction and comprising a lower channel pattern, an upper active pattern spaced apart from the lower active pattern in a second direction, the second direction intersecting the first direction, and the upper active pattern extending in the first direction, wherein the upper active pattern comprises an upper channel pattern, a gate electrode surrounding the lower channel pattern and the upper channel pattern, and the gate electrode extending in a third direction, the third direction intersecting each of the first and second directions, a lower source/drain pattern on at least one side of the lower channel pattern, an upper source/drain pattern on at least one side of the upper channel pattern, and an upper source/drain contact penetrating through the upper source/drain pattern in the second direction.

### CROSS-REFERENCE TO RELATED APPLICATION

This application claims priority to Korean Patent Application No. 10-2024-0077251, filed in the Korean Intellectual Property Office on Jun. 13, 2024, the entire contents of which are hereby incorporated by reference.

### BACKGROUND

Some example embodiments of the present disclosure relate to a semiconductor device.

Semiconductor devices may include integrated circuits including metal oxide semiconductor field effect transistors (MOSFETs). As the sizes and design rules of semiconductor devices continue to reduce, the scaling down of MOSFETs may also accelerate. As the sizes of the MOSFETs continue to reduce, operation characteristics of the semiconductor devices may deteriorate. Accordingly, various methods are being studied to form semiconductor devices with improved performance while overcoming any potential limitations caused by the higher integration of semiconductor devices.

### SUMMARY

According to some example embodiments of the present disclosure, a semiconductor device may include a lower active pattern extending in a first direction and comprising a lower channel pattern, an upper active pattern spaced apart from the lower active pattern in a second direction, the second direction intersecting the first direction, and the upper active pattern extending in the first direction, wherein the upper active pattern comprises an upper channel pattern, a gate electrode surrounding the lower channel pattern and the upper channel pattern, and the gate electrode extending in a third direction, the third direction intersecting each of the first and second directions, a lower source/drain pattern on at least one side of the lower channel pattern, an upper source/drain pattern on at least one side of the upper channel pattern, and an upper source/drain contact penetrating through the upper source/drain pattern in the second direction. The upper source/drain pattern comprises a growth portion between the upper channel pattern and the upper source/drain contact, and the growth portion having a constant thickness along the third direction, and an overgrowth portion protruding from the growth portion in the first direction.

According to some example embodiments of the present disclosure, a semiconductor device may include a lower active pattern extending in a first direction and comprising a lower channel pattern, an upper active pattern spaced apart from the lower active pattern in a second direction, the second direction intersecting the first direction, and the upper active pattern extending in the first direction, the upper active pattern comprising an upper channel pattern, a gate electrode surrounding the lower channel pattern and the upper channel pattern, and the gate electrode extending in a third direction, the third direction intersecting each of the first and second directions, a lower source/drain pattern on at least one side of the lower channel pattern, an upper source/drain pattern on at least one side of the upper channel pattern, a buried insulation pattern on at least one side of the upper source/drain pattern in the third direction, and the buried insulation pattern comprising a rounded upper surface, an etching stop film between the buried insulation pattern and the upper source/drain pattern, and an upper source/drain contact penetrating through the upper source/drain pattern in the second direction.

According to some example embodiments of the present disclosure, a semiconductor device may include a lower active pattern extending in a first direction and comprising a lower channel pattern, the lower active pattern comprising a first lower source/drain pattern on a first side of the lower channel pattern, and a second lower source/drain pattern on a second side of the lower channel pattern, an upper active pattern comprising an upper channel pattern spaced apart from the lower channel pattern in a second direction, the second direction intersecting the first direction, and, a first upper source/drain pattern on a first side of the upper channel pattern, and a second upper source/drain pattern on a second side of the upper channel pattern, a first interlayer insulation film between the second upper source/drain pattern and the second lower source/drain pattern, a gate electrode comprising a lower gate electrode surrounding the lower channel pattern, and an upper gate electrode and an outer gate electrode, the upper gate electrode and the outer gate electrode surrounding the upper channel pattern, the gate electrode extending in a third direction, the third direction intersecting each of the first and second directions, a second interlayer insulation film between the lower gate electrode and the upper gate electrode, a buried insulation pattern between the first upper source/drain pattern and the second upper source/drain pattern, and the buried insulation pattern comprising a rounded upper surface, a first etching stop film on the first lower source/drain pattern and the second lower source/drain pattern, a second etching stop film on the rounded upper surface of the buried insulation pattern, a first upper source/drain contact penetrating through the first upper source/drain pattern in the second direction, and a second upper source/drain contact penetrating through the second upper source/drain pattern and the first interlayer insulation film in the second direction, and the second upper source/drain contact contacting an upper portion of the second lower source/drain pattern. Each of the first upper source/drain pattern and the second upper source/drain pattern comprise a growth portion having a constant thickness in the third direction, an overgrowth portion protruding from the growth portion in the first direction, and a length of the overgrowth portion that protrudes in the first direction increases toward an end of the growth portion in the third direction.

According to some example embodiments of the present disclosure, the integration density of the semiconductor package can be improved.

According to some example embodiments of the present disclosure, the electrical characteristics of the semiconductor package may be improved.

### BRIEF DESCRIPTION OF THE DRAWINGS

FIG. 1 is a plan view provided to explain a semiconductor device according to some example embodiments of the present disclosure.

FIG. 2 is a perspective view schematically illustrating a part of an upper source/drain pattern according to some example embodiments of the present disclosure.

FIGS. 3A to 3C are cross-sectional views taken along line A-A′, line B-B′, and line C-C′ of FIG. 1.

FIG. 3D is a cross-sectional view of the semiconductor device according to some example embodiments of the present disclosure.

FIGS. 4A and 4B are cross-sectional views of a semiconductor device according to some example embodiments of the present disclosure.

FIG. 5 is a cross-sectional view of a semiconductor device according to some example embodiments of the present disclosure.

FIGS. 6A to 18C are cross-sectional views illustrating a method of manufacturing a semiconductor device according to some example embodiments of the present disclosure.

### DETAILED DESCRIPTION

A semiconductor device according to some example embodiments of the present disclosure will be described in detail with reference to the drawings.

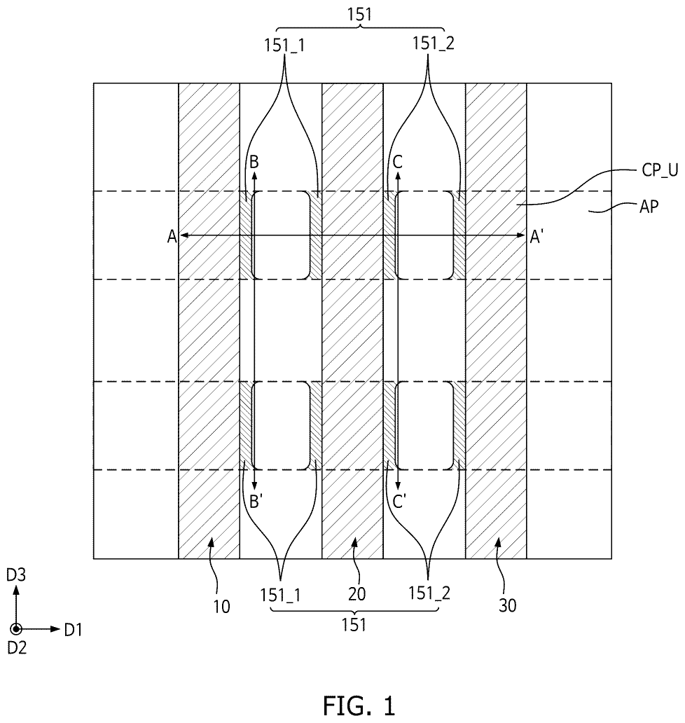

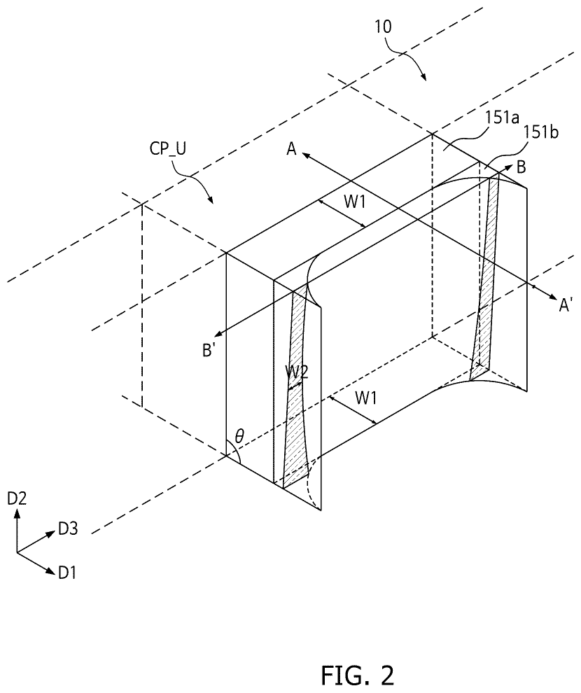

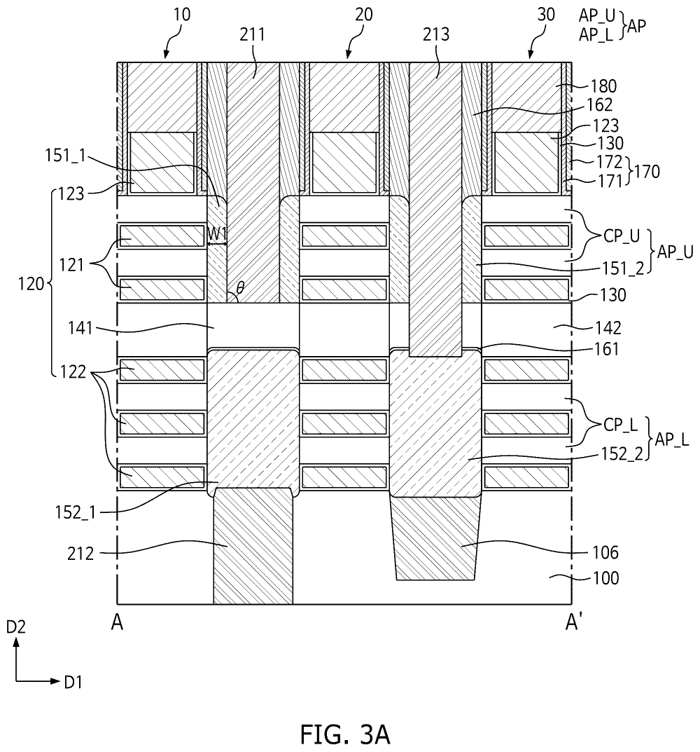

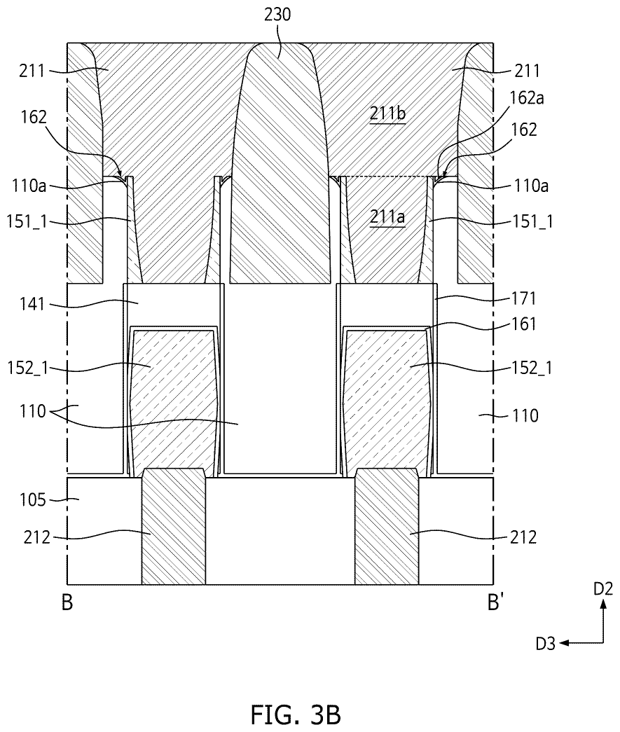

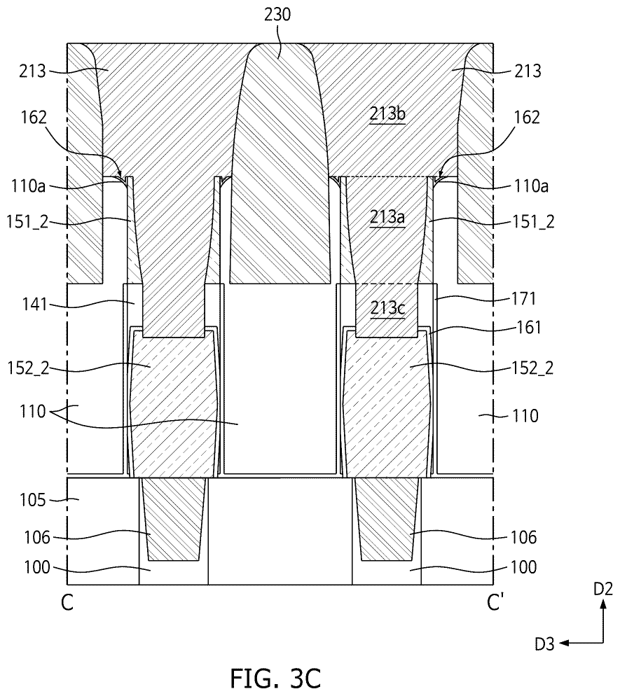

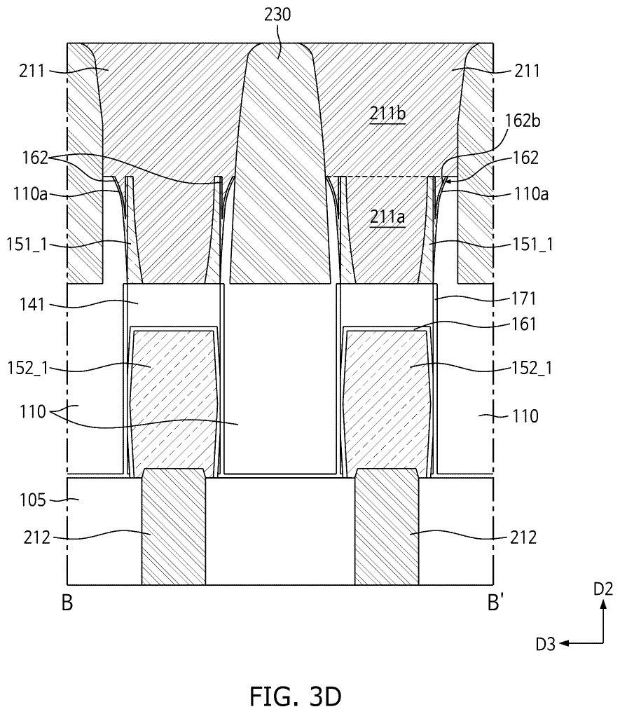

FIG. 1 is a plan view provided to explain a semiconductor device according to some example embodiments of the present disclosure. FIG. 2 is a perspective view schematically illustrating a part of an upper source/drain pattern according to some example embodiments of the present disclosure. FIGS. 3A to 3C are cross-sectional views taken along line A-A′, line B-B′, and line C-C′ of FIG. 1.

Referring to FIGS. 1, 2, 3A and 3B, the semiconductor device according to some example embodiments of the present disclosure may include a substrate 100, an active pattern AP, a gate electrode 120, a gate insulation film 130, an upper source/drain pattern 151, a lower source/drain pattern 152, etc.

The semiconductor device according to some example embodiments may include a MOSFET, and more specifically, a three-dimensional (3D) multi-stack semiconductor device which is referred to as a gate-all-around (GAA) transistor and a multi-bridge channel FET (MBCFET). The 3D multi-stack semiconductor device may be designed such that n-type and p-type semiconductor channel regions are stacked one on another, or semiconductor channel regions of the same conductivity type are stacked one on another.

The active pattern AP may be disposed on the substrate 100. The active pattern AP may extend in a first direction D1. The active pattern AP may include a lower active pattern AP_L and an upper active pattern AP_U stacked on the lower active pattern AP_L. The upper active pattern AP_U may be spaced apart from the lower active pattern AP_L in a second direction D2. The second direction D2 may be a direction intersecting (e.g., perpendicular to) the first direction D1. For example, the substrate 100 may be an insulation substrate including an insulation material (e.g., a silicon oxide and/or a silicon nitride). In another example, the substrate 100 may be a semiconductor substrate including silicon, germanium, silicon germanium, etc. However, example embodiments are not limited thereto.

The active pattern AP may be disposed to be spaced apart from the adjacent active pattern AP in a third direction D3. The third direction D3 is a direction intersecting (e.g., perpendicular to) each of the first and second directions D1 and D2. Each of the first and third directions D1 and D3 may be a direction parallel to an upper surface of the substrate 100.

The active pattern AP may be a multi-channel active pattern. The active pattern AP may include a lower active pattern AP_L and an upper active pattern AP_U. The lower active pattern AP_L may include lower channel patterns CP_L and lower source/drain patterns 152_1 and 152_2. The upper active pattern AP_U may include upper channel patterns CP_U and upper source/drain patterns 151_1 and 151_2.

The plurality of channel patterns CP_U and CP_L may be disposed on the substrate 100. The plurality of channel patterns CP_U and CP_L may be spaced apart from the substrate 100 in the second direction D2. The channel patterns CP_U and CP_L may be spaced apart from each other in the second direction D2. The second direction D2 may be a direction perpendicular to the upper surface of the substrate 100. The second direction D2 may be a thickness direction of the substrate 100. The plurality of channel patterns CP_U and CP_L may be disposed on the substrate 100 and spaced apart from each other vertically (i.e., in the second direction). The channel patterns CP_U and CP_L may have a nano sheet shape.

The plurality of channel patterns CP may include a lower channel pattern CP_L and an upper channel pattern CP_U. The lower channel pattern CP_L may be disposed on the substrate 100, and the upper channel pattern CP_U may be disposed on the lower channel pattern CP_L. Two layers (e.g., the lower channel pattern CP_L and the upper channel pattern CP_U) are illustrated as an example of the plurality of channel pattern layers, but example embodiments are not limited thereto. In addition, it is illustrated that there are three lower channel patterns CP_B and three upper channel patterns CP_U, but example embodiments are not limited thereto.

The channel patterns CP_U and CP_L may include one of an element semiconductor material such as silicon (Si) or silicon germanium (SiGe), a group IV-IV compound semiconductor, or a group III-V compound semiconductor. For example, the group IV-IV compound semiconductor may be a binary compound or a ternary compound including at least two of carbon (C), silicon (Si), germanium (Ge), and tin (Sn). However, example embodiments are not limited thereto.

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element. However, example embodiments are not limited thereto.

A field insulation film 105 may be disposed on the substrate 100. The field insulation film 105 may fill a part of a field trench. The field insulation film 105 may be disposed between adjacent substrates 100. The field insulation film 105 may extend in the first direction D1. An upper surface of the field insulation film 105 may be coplanar or substantially coplanar with the upper surface of the substrate 100.

For example, the field insulation film 105 may include an oxide, a nitride, a nitrogen oxide, or a combination thereof. Although it is illustrated that the field insulation film 105 is a single film, it is only for the convenience of description, and example embodiments are not limited thereto. For example, the field insulation film 105 may be formed of a plurality of films. However, example embodiments are not limited thereto.

The source/drain pattern may include the lower source/drain patterns 152_1 and 152_2 and the upper source/drain patterns 151_1 and 151_2. The lower source/drain patterns 152_1 and 152_2 and the upper source/drain patterns 151_1 and 151_2 may have opposite conductivity types. For example, the lower source/drain patterns 152_1 and 152_2 may have an n-type conductivity, and the upper source/drain patterns 151_1 and 151_2 may have a p-type conductivity. On the other hand, the lower source/drain patterns 152_1 and 152_2 may have a p-type conductivity, and the upper source/drain patterns 151_1 and 151_2 may have an n-type conductivity. Alternatively, the lower source/drain patterns 152_1 and 152_2 and the upper source/drain patterns 151_1 and 151_2 may have the same conductivity type.

The source/drain pattern may be an epitaxial pattern that is formed by a selective epitaxial growth (SEG) process using the active pattern AP as a seed. However, example embodiments are not limited thereto. The source/drain pattern may serve as a source/drain of a transistor that uses channel patterns CP_U and CP_L as a channel region. For example, the lower source/drain pattern 152 may serve as a source/drain of a transistor that uses the lower channel pattern CP_L as a channel region, and the upper source/drain pattern 151_1 and 151_2 may serve as a source/drain of a transistor that uses the upper channel pattern CP_U as a channel region.

The source/drain pattern may include a semiconductor material. For example, the source/drain pattern may include an element semiconductor material such as silicon (Si) or germanium (Ge). However, example embodiments are not limited thereto. In addition, for example, the source/drain pattern may include a binary or a ternary compound including at least two or more of carbon (C), silicon (Si), germanium (Ge), tin (Sn), or a compound of these doped with a group IV element. For example, the source/drain pattern may include silicon (Si), silicon-germanium (SiGe), germanium (Ge), silicon carbide (SiC), etc., but example embodiments are not limited thereto.

The source/drain pattern may include impurities doped into the semiconductor material. The doped impurities may include at least one of boron (B), phosphorus (P), carbon (C), arsenic (As), antimony (Sb), bismuth (Bi), and oxygen (O), but example embodiments are not limited thereto. For example, the source/drain patterns with p-type conductivity may include silicon-germanium (SiGe), boron-doped silicon-germanium (SiGe:B), carbon-doped silicon-germanium (SiGe:C), carbon and boron-doped silicon-germanium (SiGe:C:B), boron-doped silicon (Si:B), and silicon (Si). In addition, source/drain patterns with n-type conductivity may include phosphorus-doped silicon (Si:P), arsenic-doped silicon (Si:As), carbon-doped silicon (Si:C), arsenic and carbon-doped silicon (Si:As:C), arsenic and phosphorus-doped silicon (Si:As:P), and silicon (Si). However, example embodiments are not limited thereto.

Although it is illustrated that the source/drain pattern is a single film, it is only for the convenience of description, and example embodiments are not limited thereto. The source/drain pattern may include a plurality of layers including different materials. In another example, the source/drain pattern may include the same material and may include a plurality of layers having different concentrations of constituent materials (e.g., concentrations of germanium (Ge)).

The source/drain pattern may be disposed on at least one side of the gate electrode 120. The source/drain pattern may be disposed between adjacent gate electrodes 120 in the first direction D1. For example, the upper source/drain patterns 151_1 and 151_2 may be disposed on both sides of an upper gate electrode 121. The lower source/drain patterns 152_1 and 152_2 may be disposed on both sides of a lower gate electrode 122.

The lower source/drain pattern 152_1 and 152_2 may be disposed on at least one side of the lower channel pattern CP_L and connected with the lower channel pattern CP_L. A part of the lower source/drain pattern 152_1 and 152_2 may be in contact with the lower channel pattern CP_L. The other part of the lower source/drain pattern 152_1 and 152_2 may be in contact with the gate insulation film 130. The lower source/drain pattern 152_1 and 152_2 may be disposed between the lower channel patterns CP_L spaced apart from each other in the first direction D1. The lower source/drain pattern 152_1 and 152_2 may connect the lower channel patterns CP_L of the channel patterns CP_U and CP_L spaced apart from each other in the first direction D1.

A first etching stop film 161 may be provided on the lower source/drain pattern 152_1 and 152_2. A first interlayer insulation film 141 may be provided on the first etching stop film 161. The first interlayer insulation film 141 may cover the first etching stop film 161 and the lower source/drain patterns 152_1 and 152_2.

A first lower source/drain contact 212 may be provided under the first lower source/drain pattern 152_1. The lower source/drain contact 212 may be electrically connected with the first lower source/drain pattern 152_1. For example, the lower source/drain contact 212 may penetrate through the upper surface of the substrate 100. The lower source/drain contact 212 may include at least one of copper (Cu), aluminum (Al), ruthenium (Ru), cobalt (Co), tungsten (W), molybdenum (Mo), and a combination thereof. However, example embodiments are not limited thereto.

A lower insulation pattern 106 may be provided under the second lower source/drain pattern 152_2. The lower insulation pattern 106 may cover a lower portion of the second lower source/drain pattern 152_2. The substrate 100 may be provided under the lower insulation pattern 106. The substrate 100 may cover the lower insulation pattern 106.

The upper source/drain pattern 151_1 and 151_2 may be disposed on the first interlayer insulation film 141. The first interlayer insulation film 141 may be disposed between the lower source/drain pattern 152_1 and 152_2 and the upper source/drain pattern 151_1 and 151_2 to isolate and insulate the lower source/drain pattern 152_1 and 152_2 and the upper source/drain pattern 151_1 and 151_2 from each other.

The upper source/drain pattern 151_1 and 151_2 may be disposed on at least one side of the upper channel pattern CP_U. The upper source/drain pattern 151_1 and 151_2 may be disposed on one side of the upper channel pattern CP_U, and may be disposed on one side of the adjacent upper channel pattern CP_U. For example, the first upper source/drain pattern 151_1 may be disposed between a first gate structure 10 and a second gate structure 20. The first upper source/drain pattern 151_1 may be grown from the upper channel pattern CP_U of the first gate structure 10 and the upper channel pattern CP_U of the first gate structure 10. The first upper source/drain patterns 151_1 may be disposed to face each other between the first gate structure 10 and the second gate structure 20.

A part of the upper source/drain pattern 151_1 and 151_2 may be in contact with the upper channel pattern CP_U. The upper source/drain pattern 151_1 and 151_2 may be disposed between the upper channel patterns CP_U spaced apart from each other in the first direction D1.

The first to third gate structures 10, 20 and 30 may be spaced apart from one another in the first direction D1. The first to third gate structures 10, 20 and 30 may extend in the third direction D3. The first to third gate structures 10, 20 and 30 may intersect the upper active pattern AP_U and the lower active pattern AP_L.

The first to third gate structures 10, 20 and 30 may include a plurality of gate electrodes 120 surrounding the upper and lower channel patterns CP_U and CP_L. The plurality of gate electrodes 120 may be provided on the upper and lower channel patterns CP_U and CP_L. The first to third gate structures 10, 20 and 30 may include a lower channel pattern CP_L disposed on the lower channel patterns CP_L, an upper gate electrode 121 disposed on the upper channel patterns CP_U, and an outer gate electrode 123 disposed on a channel pattern positioned at an uppermost end among the upper channel patterns CP_U. The upper gate electrode 121 and the outer gate electrode 123 may surround the upper channel pattern CP_U.

Although it is illustrated that the gate electrode 120 is a single film, example embodiments are not limited thereto. For example, the gate electrode 120 may include a work function control film for controlling a work function, and a filling conductive film for filling a space formed by the work function control film. The work function control film may include, for example, at least one of TiN, TaN, TiC, TaC, TiAlC, and a combination thereof. For example, the filling conductive film may include W or Al. However, example embodiments are not limited thereto.

A second interlayer insulation film 142 may be disposed between the upper channel pattern CP_U and the lower channel pattern CP_L. The second interlayer insulation film 142 may isolate the upper gate electrode 121 and the lower gate electrode 122 from each other.

Referring to FIGS. 2 and 3A, the first upper source/drain pattern 151_1 may be grown from the upper channel pattern CP_U surrounded by the first gate structure 10 and the upper channel pattern CP_U surrounded by the second gate structure 20. That is, as the first upper source/drain patterns 151_1 grow at positions spaced apart from each other, the first upper source/drain patterns may have isolated structures. Hereinafter, the first upper source/drain pattern 151_1 will be described based on the first upper source/drain pattern 151_1 grown from the upper channel pattern CP_U surrounded by the first gate structure 10, and description of the first upper source/drain pattern 151_1 may be equally applicable to the second upper source/drain pattern 151_2.

The first upper source/drain pattern 151_1 may include a growth portion 151a grown from the upper channel pattern CP_U by a desired (and/or alternatively predetermined) thickness in the first direction D1, and an overgrowth portion 151b protruding from the growth portion 151a in the first direction D1.

The growth portion 151a may have a thickness W1 in the first direction D1. The thickness W1 of the growth portion 151a in the first direction D1 may be constant in the third direction D3. For example, the thickness W1 of the growth portion 151a in the first direction D1 may be constant along the third direction D3. The growth portion 151a may have the same width as that of the upper channel pattern CP_U in the second and third directions D2 and D3, and may have the thickness W1 of the first direction D1 which is constant along the third direction D3.

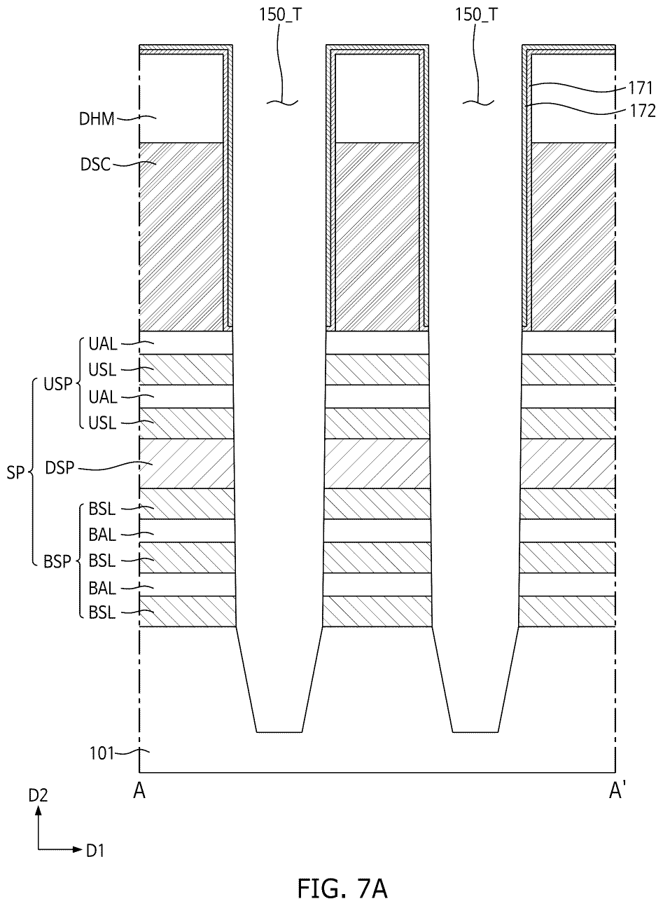

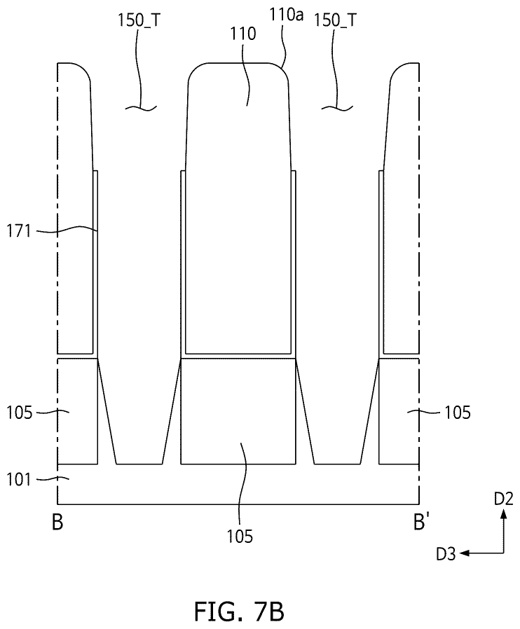

Meanwhile, the plurality of channel patterns CP_U and CP_L may be isolated from each other by a trench 150_T (see FIG. 7A). The trench 150_T may be formed by an etching process, and may have a width gradually reduced in the depth direction. The width of the plurality of channel patterns CP_U and CP_L in the first direction D1 may increase toward the substrate 100. That is, the width of the upper channel pattern CP_U in the first direction D1 may increase toward the lower channel pattern CP_L. The angle between a side surface of the upper channel pattern CP_U and a lower surface of the first upper source/drain pattern 151_1 may be angle θ. The angle θ may be an obtuse angle.

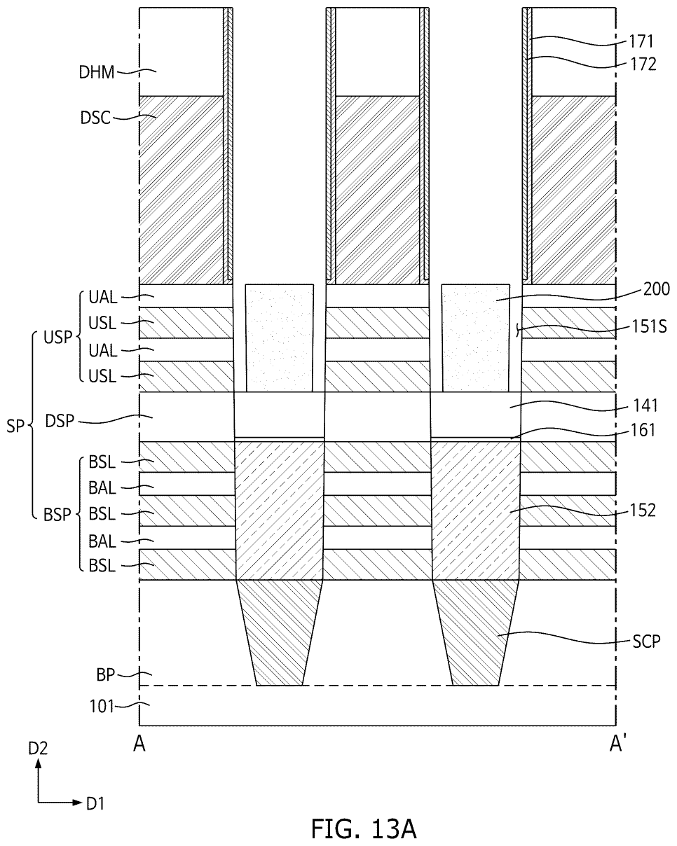

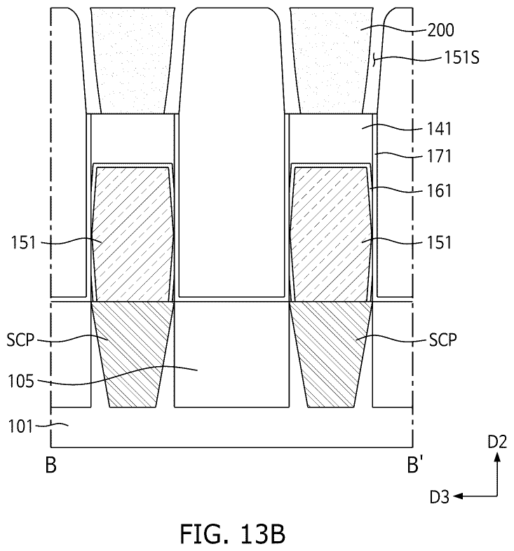

For example, the first upper source/drain pattern 151_1 disposed on one side of the first gate structure 10 may be grown from the upper channel pattern CP_U surrounded by the first gate structure 10. A shape of the first upper source/drain pattern 151_1 may be determined by an epitaxial growth space 151S (see FIG. 13A) in the manufacturing process. However, example embodiments are not limited thereto. That is, the shape of the first upper source/drain pattern 151_1 may be defined by the epitaxial growth space 151S and the upper channel pattern CP_U serving as a seed. If the first upper source/drain pattern 151_1 grows for a sufficient time, the growth may be limited by the epitaxial growth space 151S and the upper channel pattern CP_U.

The first upper source/drain patterns 151_1 may be disposed to face each other between the first gate structure 10 and the second gate structure 20. This may be because the first upper source/drain patterns 151_1 are formed after a filler 200 (see FIG. 13A) is formed between the upper channel pattern CP_U of the first gate structure 10 and the upper channel pattern CP_U of the second gate structure 20.

The growth portion 151a may be formed to be inclined in the same direction as the direction in which the upper channel pattern CP_U is inclined. For example, the lower end of the growth portion 151a grown from the first gate structure 10 may be positioned closer to the second gate structure 20 than the upper end of the growth portion 151a. Specifically, since the width of the upper channel pattern CP_U becomes gradually wider toward the lower channel pattern CP_L, the lower end of the growth portion 151a may be determined to have a shape closer to the second gate structure 20 than the upper end of the growth portion 151a. Referring to FIG. 3A, the first upper source/drain pattern 151_1 may form the desired (and/or alternatively predetermined) angle θ with the first interlayer insulation film 141. The desired (and/or alternatively predetermined) angle may be an obtuse angle.

The overgrowth portion 151b may protrude from the growth portion 151a in the first direction D1. The overgrowth portion 151b may protrude from both ends of the growth portion 151a in the third direction D3. The overgrowth portion 151b may protrude from one end and the other end of the growth portion 151a in the third direction D3 and may be formed as a pair. A length of the overgrowth portion 151b protruding in the first direction D1 may increase toward the end of the growth portion 151a. The length of the overgrowth portion 151b protruding in the first direction D1 may increase toward the end of the growth portion 151a along the third direction D3.

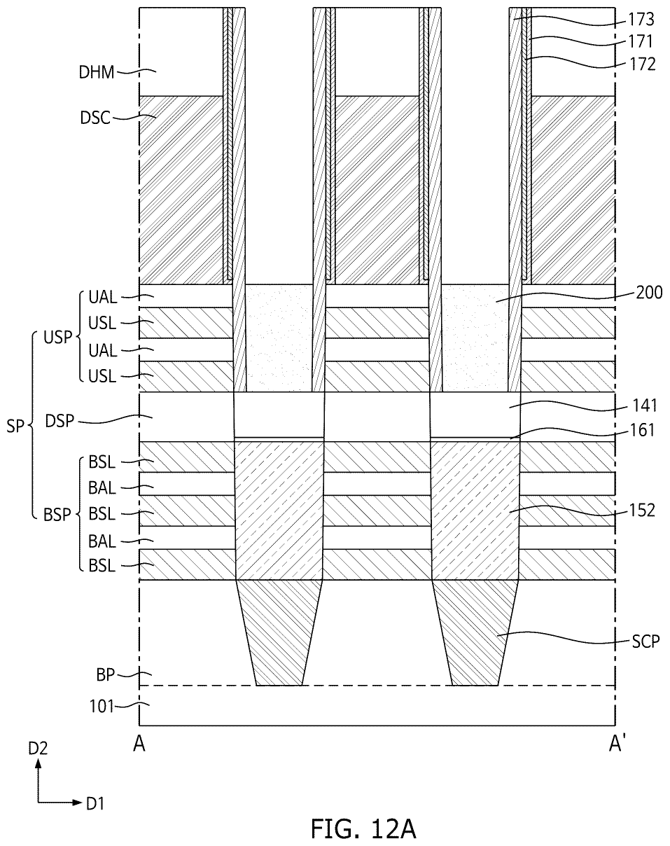

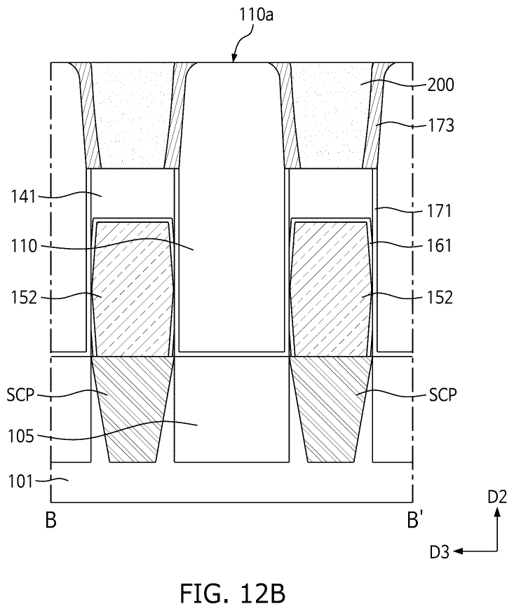

A profile of the overgrowth portion 151b may be formed by the epitaxial growth space 151S. A shape of the overgrowth portion 151b protruding from the growth portion 151a may be formed by a sacrificial liner 173 (see FIG. 12B) for forming the epitaxial growth space 151S. A shape of the sacrificial liner 173 may be formed by a rounded upper surface 110a of a buried insulation pattern 110. As a result, due to the profile by etching the buried insulation pattern 110, the overgrowth portion 151b may have a shape protruding from the growth portion 151a.

The overgrowth portion 151b may have a width W2 in the third direction D3. The width W2 of the overgrowth portion 151b may increase from an upper end to a lower end of the first upper source/drain pattern 151_1. Referring to FIG. 2, the width W2 may gradually increase toward the lower end in the cross section of the overgrowth portion 151b.

As such, in the semiconductor device according to some example embodiments of the present disclosure, the first upper source/drain pattern 151_1 may have a structure based on a profile of each of the epitaxial growth space 151S in which the growth of the first upper source/drain pattern 151_1 is limited to a desired (and/or alternatively predetermined) shape, the rounded upper surface 110a of the buried insulation pattern 110, and the upper channel pattern CP_U.

According to a comparative example, after the upper source/drain pattern connects the upper channel pattern of the first gate structure and the upper channel pattern of the second gate structure, a hole may be formed in the upper source/drain pattern through etching or the like, and an upper source/drain contact may be formed by filling the hole with a metallic material. According to the comparative example, a profile of the upper source/drain pattern may be formed by epitaxial growth of the upper source/drain pattern and etching for hole formation. In addition, according to the comparative example, since the buried insulation pattern is not formed, the upper source/drain pattern may be grown horizontally and excessively.

A first upper source/drain contact 211 may be provided in the first upper source/drain pattern 151_1. The first upper source/drain contact 211 may penetrate through the first upper source/drain pattern 151_1. The first upper source/drain contact 211 may be in contact with the upper surface of the first interlayer insulation film 141. The first upper source/drain contact 211 may be disposed between the isolated first upper source/drain patterns 151_1. The first upper source/drain contact 211 may be disposed between sidewalls of second etching stop films 162. The first upper source/drain contact 211 may be connected with an upper wiring.

The first upper source/drain contact 211 may include a first portion 211a disposed at the same vertical level as the first upper source/drain pattern 151_1. The first portion 211a may be disposed between the isolated first upper source/drain patterns 151_1. A part of the first portion 211a may fill an indentation portion 162a of the second etching stop film 162, which will be described below.

The first upper source/drain contact 211 may include a second portion 211b disposed at a higher vertical level than the first upper source/drain pattern 151_1. The second portion 211b may be disposed between contact insulation patterns 230. The upper surface of the second portion 211b may be coplanar or substantially coplanar with the upper surfaces of the contact insulation patterns 230.

A second upper source/drain contact 213 may be provided in the second upper source/drain pattern 151_2. The second upper source/drain contact 213 may penetrate through the second upper source/drain pattern 151_2. The second upper source/drain contact 213 may penetrate through the first interlayer insulation film 141 and the first etching stop film 161. The second upper source/drain contact 213 may be in contact with an upper portion of the second lower source/drain pattern 152_2. The second upper source/drain contact 213 may be electrically connected to both the first upper source/drain pattern 151_1 and the second upper source/drain pattern 151_2 in contact therewith.

The second upper source/drain contact 213 may be disposed between sidewalls of the second etching stop films 162. The second upper source/drain contact 213 may be connected to an upper wiring.

The second upper source/drain contact 213 may include a first portion 213a disposed at the same vertical level as the second upper source/drain pattern 151_2. The first portion 213a may be disposed between the isolated second upper source/drain patterns 151_2. A part of the first portion 213a may fill the indentation portion 162a of the second etching stop film 162, which will be described below.

The second upper source/drain contact 213 may include a second portion 213b disposed at a higher vertical level than the second upper source/drain pattern 151_2. The second portion 213b may be disposed between the contact insulation patterns 230. The upper surface of the second portion 213b may be coplanar or substantially coplanar with the upper surface of the contact insulation pattern 230.

The second upper source/drain contact 213 may include a third portion 213c disposed at a lower vertical level than the second upper source/drain pattern 151_2. The third portion 213c may penetrate through the first interlayer insulation film 141 and the first etching stop film 161. The third portion 213c may be in contact with an upper portion of the second lower source/drain pattern 152_2.

The width of the first portion 213a in the third direction D3 may be larger than the width of the third portion 213c in the third direction D3. The shape of the first portion 213a in the third direction D3 may be defined by the second upper source/drain pattern 151_2. The width W2 of the overgrowth portion 151b of the second upper source/drain pattern 151_2 in the third direction D3 may gradually increase toward the lower end. Accordingly, the width of the first portion 213a in the third direction D3 may gradually decrease toward the lower end. The third portion 213c may extend downward from the lower end of the first portion 213a. That is, since the third portion 213c extends from the narrowest portion of the first portion 213a, the width of the third portion 213c in the third direction D3 may be smaller than the width of the first portion 213a in the third direction D3. The shapes of the first upper source/drain contact 211 and the second upper source/drain contact 213 may be defined according to the shapes of the first upper source/drain pattern 151_1 and the second upper source/drain pattern 151_2. Since the first upper source/drain pattern 151_1 and the second upper source/drain pattern 151_2 have the same shape, descriptions will be made based on the first upper source/drain pattern 151_1 and the first upper source/drain contact 211.

The width of the first upper source/drain contact 211 in the first direction D1 may decrease toward the first lower source/drain pattern 152_1. The width of the upper channel pattern CP_U in the first direction D1 may increase toward the lower channel pattern CP_L, and the thickness of the growth portion 151a of the first upper source/drain pattern 151_1 may be constant. Accordingly, the width of the first upper source/drain contact 211 in the first direction D1 may decrease toward the first lower source/drain pattern 152_1. Referring to FIG. 3A, the angle θ formed by the first upper source/drain contact 211 and the upper surface of the first interlayer insulation film 141 may be an obtuse angle.

The buried insulation pattern 110 may be provided on the substrate 100 and the field insulation film 105. The buried insulation pattern 110 may be disposed on at least one side of the upper source/drain pattern 151_1 and 151_2 in the third direction D3. The buried insulation pattern 110 may be positioned between the lower source/drain patterns 152_1 and 152_2 adjacent to each other in the third direction D3. The buried insulation pattern 110 may extend along the second direction D2 to be adjacent to sidewalls of the lower source/drain patterns 152_1 and 152_2 and sidewalls of the upper source/drain patterns 151_1 and 151_2. That is, the buried insulation pattern 110 may face the sidewalls of the lower source/drain patterns 152_1 and 152_2 and the sidewalls of the upper source/drain patterns 151_1 and 151_2. A plurality of buried insulation patterns 110 may be provided to be spaced apart from one another in the first and third directions D1 and D3.

The buried insulation pattern 110 may have a rounded upper surface 110a. The profile of the recessed upper surface 110a of the buried insulation pattern 110 may be a result obtained in a process of forming the trench 150_T (see FIG. 7B) in the manufacturing process. A part of the rounded upper surface 110a of the buried insulation pattern 110 may be curved. Specifically, corner portions of the rounded upper surface 110a of the buried insulation pattern 110 that are adjacent to the first and second upper source/drain patterns 151_1 and 151_2 may be curved.

A horizontal surface of the rounded upper surface 110a of the buried insulation pattern 110 may be positioned at the same level as the uppermost ends of the upper source/drain patterns 151_1 and 151_2. For example, the buried insulation pattern 115 may include a silicon-based insulation material (e.g., a silicon oxide, a silicon oxynitride, or a silicon nitride). However, example embodiments are not limited thereto.

A first spacer film 171 covering a sidewall and a bottom surface of the buried insulation pattern 110 may be provided. For example, the first spacer film 171 may be interposed between a sidewall of the buried insulation pattern 110 and a sidewall of the lower source/drain pattern 152_1 and 152_2, and between the bottom surface of the buried insulation pattern 110 and the substrate 100 and the field insulation film 105. That is, the first spacer film 171 may cover the upper surfaces of the substrate 100 and the field insulation film 105, and may vertically extend along the sidewall of the buried insulation pattern 110 to be in contact with the lower source/drain patterns 152_1 and 152_2, the first interlayer insulation film 141, the upper source/drain patterns 151_1 and 151_2, and the first and second etching stop films 162.

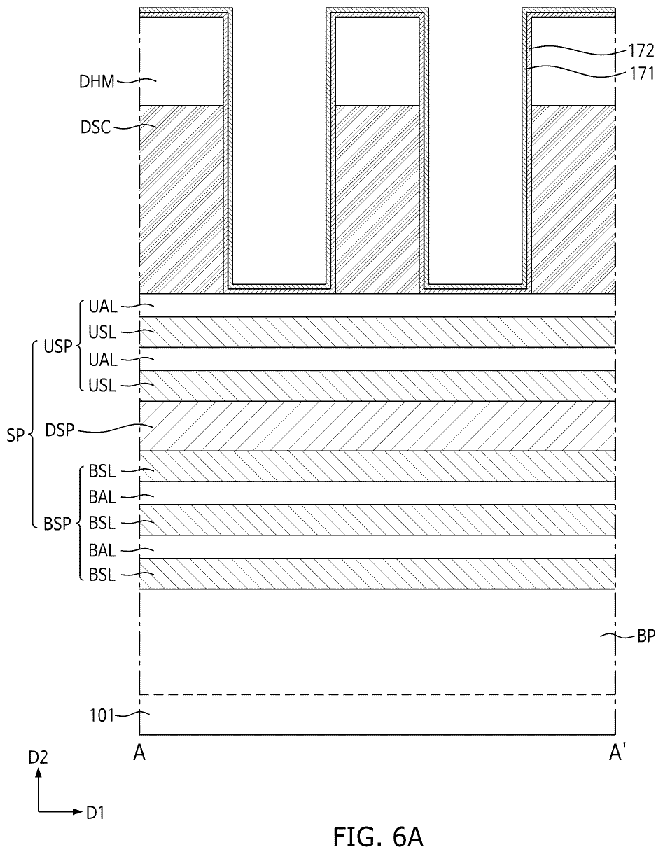

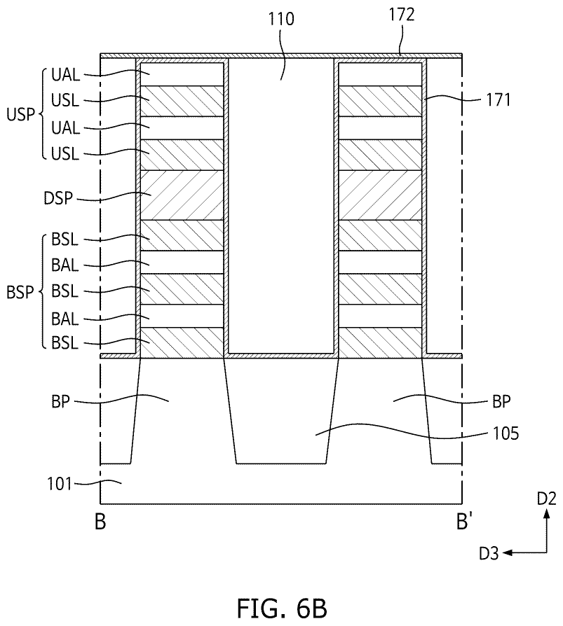

The first spacer film 171 may reduce or prevent a stack pattern SP (see FIG. 6A) from being oxidized by the buried insulation pattern 110 during the manufacturing process. For example, the first spacer film 171 may include at least one of SiCN, SiCON, and SiN. However, example embodiments are not limited thereto.

The second etching stop film 162 may be provided on the rounded upper surface 110a of the buried insulation pattern 110. The second etching stop film 162 may be interposed between the upper source/drain pattern 151_1 and 151_2 and the rounded upper surface 110a of the buried insulation pattern 110. Specifically, it may be disposed in a space between the corner portion of the rounded upper surface 110a of the buried insulation pattern 110 and the upper source/drain pattern 151_1 and 151_2. The second etching stop film 162 may partially cover the rounded upper surface 110a of the buried insulation pattern 110.

The second etching stop film 162 may be deposited in a space between the upper source/drain pattern 151_1 and 151_2 and the rounded upper surface 110a of the buried insulation pattern 110. The second etching stop film 162 may be deposited along the shapes of the curved surface of the rounded upper surface 110a and the side surface of the upper source/drain pattern 151_1 and 151_2. That is, the second etching stop film 162 may form the indentation portion 162a. If the second etching stop film 162 is conformally formed, the shape of the indentation portion 162a may be the same as the shape of the curved surface of the rounded upper surface 110a and the shape of the side surface of the upper source/drain pattern 151_1 and 151_2. A part of the upper source/drain contact 211 may fill the indentation portion 162b.

The contact insulation pattern 230 may be provided on the buried insulation pattern 110. The contact insulation pattern 230 may penetrate through the rounded upper surface 110a of the buried insulation pattern 110. The contact insulation pattern 230 may be disposed to penetrate through the upper surface 110a of the buried insulation pattern 110 in the second direction D2.

The contact insulation pattern 230 may be disposed on at least one side of the upper source/drain contact 211, 213 in the third direction D3. The contact insulation pattern 230 may be disposed on at least one side of the first and second upper source/drain contacts 211, 213 in the third direction D3. The upper surface of the contact insulation pattern 230 may be coplanar or substantially coplanar with the upper surfaces of the first and second upper source/drain contacts 211, 213. The bottom surface of the contact insulation pattern 230 may be coplanar or substantially coplanar with the lower ends of the first and second upper source/drain patterns 151_1 and 151_2. In another example, the bottom surface of the contact insulation pattern 230 may be disposed at the same level as the first and second lower source/drain patterns 152_1 and 152_2. That is, the contact insulation pattern 230 may penetrate through the buried insulation pattern 110 more deeply in the second direction D2.

The gate electrode 120 may extend on the substrate 100 in the third direction D3. The gate electrode 120 may intersect the active pattern AP. The gate electrode 120 may be disposed to be spaced apart from the gate electrode 120 adjacent thereto in the first direction D1. The gate electrode 120 may surround the channel patterns CP_U and CP_L.

The gate electrode 120 may include an upper gate electrode 121, a lower gate electrode 122, and an outer gate electrode 123. The lower gate electrode 122 may be disposed on the lower channel pattern CP_L. The lower gate electrode 122 may be disposed to surround the lower channel pattern CP_L. The upper gate electrode 121 may be disposed on the upper channel pattern CP_U. The outer gate electrode 123 may be disposed on the upper channel pattern CP_U. The outer gate electrode 123 may surround the upper channel pattern CP_U together with the upper gate electrode 121.

The gate electrode 120 may include at least one of a metal, a metal alloy, a conductive metal nitride, a metal silicide, a doped semiconductor material, a conductive metal oxide, and a conductive metal oxynitride. For example, the gate electrode 120 may contain at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but example embodiments are not limited thereto. The conductive metal oxide and the conductive metal oxynitride may include a form in which the above-described material is oxidized, but example embodiments are not limited thereto.

The gate insulation film 130 may be disposed between the gate electrode 120 and the plurality of channel patterns CP_U and CP_L, and between the gate electrode 120 and the upper and lower source/drain patterns 152_1 and 152_2. For example, the gate insulation film 130 may be disposed between the lower gate electrode 120_B and the lower channel pattern CP_L.

For example, the gate insulation film 130 may contain one or more of silicon oxide, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. However, example embodiments are not limited thereto.

A gate capping pattern 180 may be disposed on the upper gate electrode 121. The gate capping pattern 180 may cover the upper surface of the outer gate electrode 123. The gate capping pattern 180 may overlap the outer gate electrode 123 in the second direction D2. The gate capping pattern 180 may extend along the gate electrode 120 in the third direction D3. The gate capping pattern 180 may be disposed between gate spacers 170. A side surface of the gate capping pattern 180 may be in contact with the gate spacer 170.

For example, the gate capping pattern 180 may include at least one of silicon nitride (SiN), silicon oxynitride (SiON), silicon carbon nitride (SiCN), silicon oxycarbonitride (SiOCN), and a combination thereof. However, example embodiments are not limited thereto.

The gate spacer 170 may include a first spacer film 171 and a second spacer film 172 disposed on the first spacer film 171. The first and second spacer films 171 and 172 may extend along a side surface of the upper gate electrode 121 and a side surface of the gate capping pattern 180 disposed on the upper gate electrode 121.

The first and second spacer films 171 and 172 may extend along the gate electrode 120 in the third direction D3. The upper surfaces of the first and second spacer films 171 and 172 may be positioned at a higher level than the upper surface of the upper gate electrode 121. For example, the upper surfaces of the first spacer film 171 may be coplanar or substantially coplanar with the upper surface of the gate capping pattern 180.

Each of the second spacer films 172 may include at least one of SiCN, SiCON, and SiN. In addition, the second spacer film 172 may further include a low-k material (e.g., an air or porous film). The permittivity of the second spacer film 172 may be smaller than the permittivity of the first spacer film 171.

In some examples, the gate insulation film 130 may be further disposed between the upper gate electrode 121 and the channel pattern CP and between the upper gate electrode 121 and the first spacer film 171. In another example, it may not be disposed between the upper gate electrode 121 and the first spacer film 171. For example, the gate insulation film 130 may not be disposed between the first spacer film 171 and the upper gate electrode 121 and between the first spacer film 171 and the gate capping pattern 180. However, example embodiments are not limited thereto.

The second etching stop film 162 may be provided on the gate capping pattern 180 and the second spacer film 172. The second etching stop film 162 may cover a sidewall of the second spacer film 172.

Hereinafter, a semiconductor device according to other example embodiments of the present disclosure will be described. The same reference numerals are used for the same components as in the above-described examples, and detailed description thereof may be omitted.

FIG. 3D is a cross-sectional view of the semiconductor device according to some example embodiments of the present disclosure.

FIG. 3D is a cross-sectional view of the semiconductor device, taken along line B-B′ of FIG. 1, according to some example embodiments of the present disclosure.

Referring to FIG. 3D, in the semiconductor device according to some examples of the disclosure, the buried insulation pattern 110 and the upper source/drain patterns 151_1 and 151_2 may be spaced apart from each other. That is, a space may be formed between the buried insulation pattern 110 and the upper source/drain patterns 151_1 and 151_2.

The profile of the buried insulation pattern 110 according to some example embodiments may appear if the buried insulating pattern 110 is more excessively etched in the etching process of forming the trench 150_T (see FIG. 7B).

The second etching stop film 162 may be provided between the buried insulation pattern 110 and the upper source/drain patterns 151_1 and 151_2. The second etching stop film 162 may fill a space between the buried insulation pattern 110 and the upper source/drain patterns 151_1 and 151_2. The second etching stop film 162 may fill along a space between the buried insulation pattern 110 and the upper source/drain patterns 151_1 and 151_2.

A part of the second etching stop film 162 may be interposed between the upper source/drain patterns 151_1 and 151_2 and the rounded upper surface 110a of the buried insulation pattern 110. The second etching stop film 162 may partially cover the rounded upper surface 110a of the buried insulation pattern 110.

The second etching stop film 162 may be deposited in a space between the upper source/drain patterns 151_1 and 151_2 and the buried insulation pattern 110. The second etching stop film 162 may be deposited along the shapes of the rounded upper surface 110a and a sidewall of the buried insulation pattern 110, and a side surface of the upper source/drain pattern 151_1 and 151_2. That is, the second etching stop film 162 may form the indentation portion 162b. If the second etching stop film 162 is conformally formed, the shape of the indentation portion 162b may be the same as the shape of the curved surface of the rounded upper surface 110a and the side surface of the upper source/drain pattern 151_1 and 151_2. A part of the upper source/drain contact 211 may fill the indentation portion 162b.

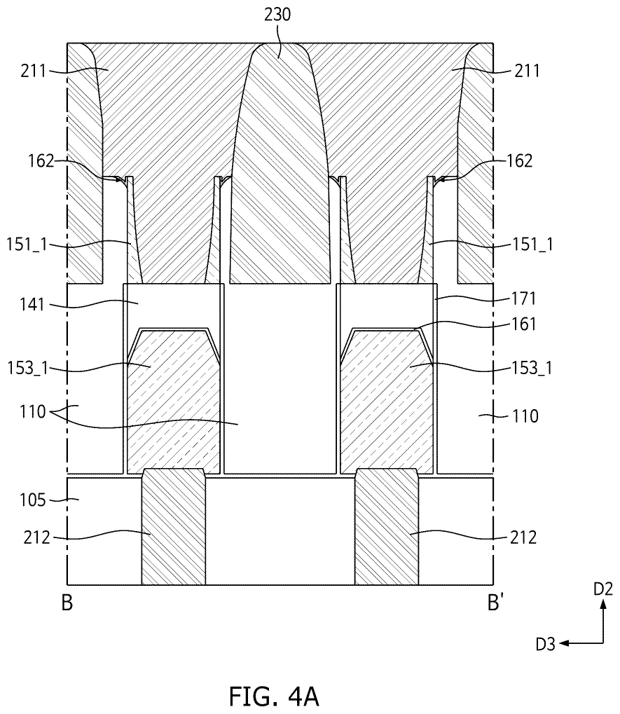

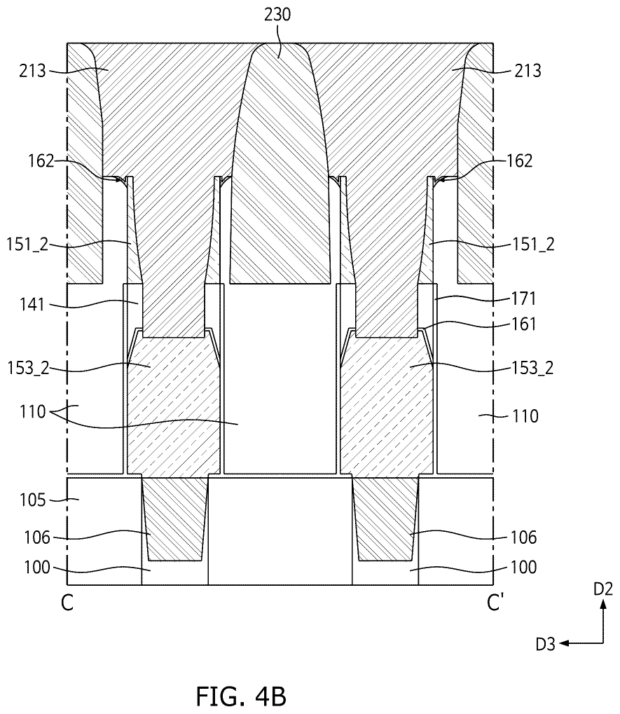

FIGS. 4A and 4B are cross-sectional views of a semiconductor device according to some example embodiments of the present disclosure.

Referring to FIGS. 4A and 4B, the semiconductor device according to some example embodiments of the present disclosure may include lower source/drain patterns 153_1 and 153_2. The lower source/drain pattern 153_1 and 153_2 may be disposed between buried insulation patterns 110. The buried insulation pattern 110 may be disposed on one side of the lower source/drain pattern 153_1 and 153_2 in the third direction D3. A first spacer film 171 may be disposed on the buried insulation pattern 110.

The lower source/drain pattern 153_1 and 153_2 may be formed between the first spacer films 171. The lower source/drain patterns 153_1 and 153_2 may be grown through a selective epitaxial growth (SEG) process. If the lower source/drain patterns 153_1 and 153_2 are grown for a sufficient time, a space between the first spacer films 171 may be filled. That is, the lower source/drain patterns 153_1 and 153_2 may be disposed on a field insulation film 105 and sidewalls of the buried insulation pattern 110.

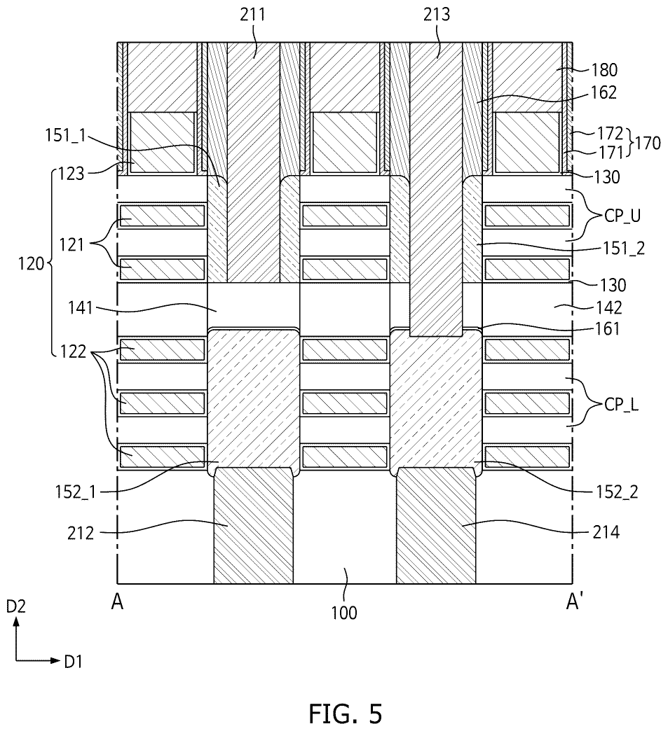

FIG. 5 is a cross-sectional view of a semiconductor device according to some example embodiments of the present disclosure.

The semiconductor device according to some example embodiments of the present disclosure may include a first lower source/drain contact 212 contacting a lower portion of a first lower source/drain pattern 152_1, and a second lower source/drain contact 214 contacting a lower portion of a second lower source/drain pattern 152_2. The second lower source/drain contact 214 may penetrate through a substrate 100. The second lower source/drain contact 214 may be electrically connected with a lower portion of the second lower source/drain pattern 152_2.

The second upper source/drain pattern 151_2 and the second lower source/drain pattern 152_2 may receive the same signal. Each of the second upper source/drain pattern 151_2 and the second lower source/drain pattern 152_2 may receive a signal from at least one of the second upper source/drain contact 213 and the second lower source/drain contact 214. For example, the second upper source/drain pattern 151_2 may receive a signal from the second upper source/drain contact 213 or may receive a signal from the second lower source/drain contact 214. Likewise, the second lower source/drain pattern 152_2 may receive a signal from the second upper source/drain contact 213 or may receive a signal from the second lower source/drain contact 214.

FIGS. 6A to 18C are cross-sectional views illustrating a method of manufacturing a semiconductor device according to some example embodiments of the present disclosure.

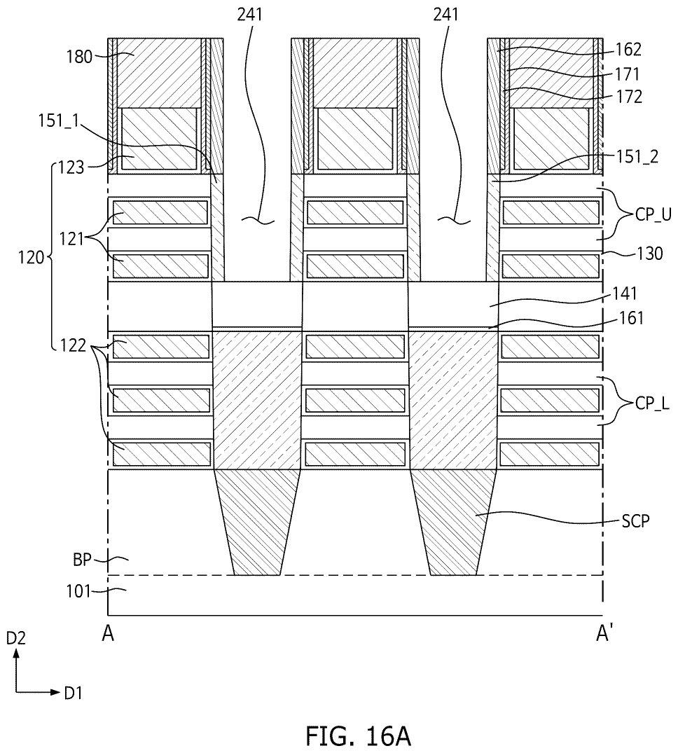

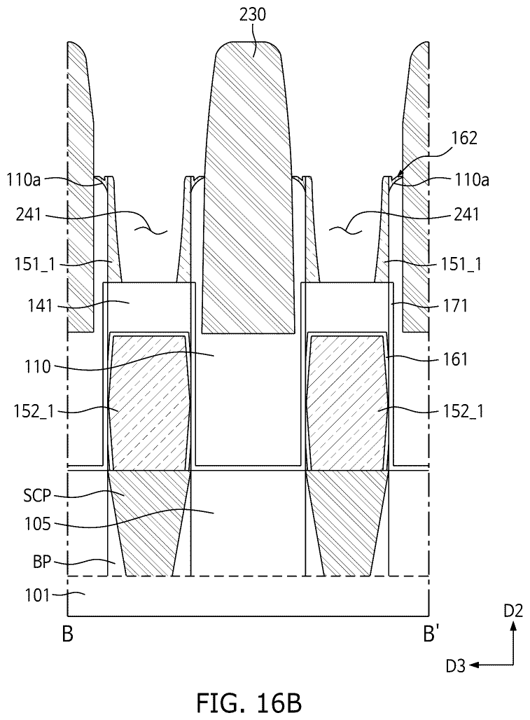

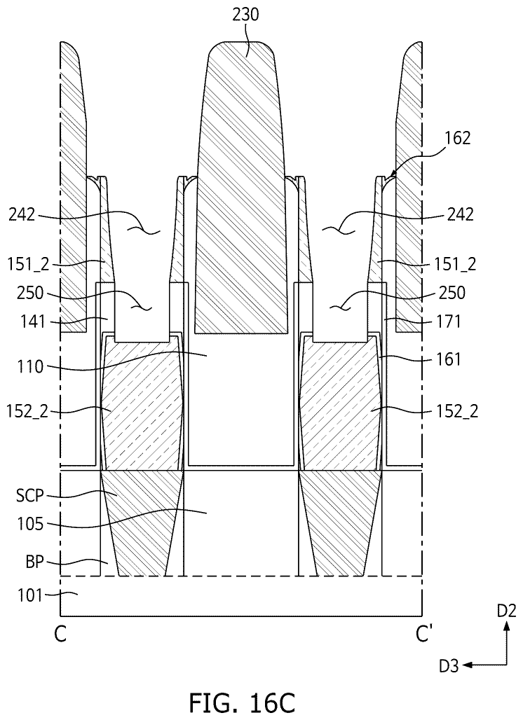

FIGS. 5A, 6A, 7A, 8A, 9A, 10A, 11A, 12A, 13A, 14A, 15A, 16A, 17A, and 18A are cross-sectional views taken on line A-A′ of FIG. 1. FIGS. 5B, 6B, 7B, 8B, 9B, 10B, 11B, 12B, 13B, 14B, 15B, 16B, 17B, and 18B are cross-sectional views taken on line B-B′ of FIG. 1. FIGS. 16C, 17C, and 18C are cross-sectional views taken on line C-C′ of FIG. 1.

Referring to FIGS. 6A and 6B, the semiconductor substrate 101 may be provided. The semiconductor substrate 101 may include any one of silicon (Si), germanium (Ge), and silicon-germanium (SiGe). For example, the semiconductor substrate 101 may be a single crystal silicon wafer. However, example embodiments are not limited thereto.

A lower stack pattern BSP in which lower sacrificial layers BSL and lower active layers BAL are alternately stacked may be formed on the semiconductor substrate 101. For example, the lower sacrificial layers BSL may include silicon germanium (SiGe), and the lower active layers BAL may include silicon (Si). However, example embodiments are not limited thereto. A concentration of germanium (Ge) of each of the lower sacrificial layers BSL may be 10 at % to 30 at %.

A separation stack pattern DSP may be formed on the lower sacrificial layer BSL of the uppermost layer. The thickness of the separation stack pattern DSP may be greater than the thickness of the lower sacrificial layer BSL. The separation stack pattern DSP may include silicon germanium (SiGe). A concentration of germanium (Ge) of the separation stack pattern DSP may be greater than a concentration of germanium (Ge) of the lower sacrificial layer BSL. However, example embodiments are not limited thereto. For example, the concentration of germanium (Ge) of the separation layer DSL may be 40 at % to 90 at %.

An upper stack pattern USP in which upper sacrificial layers USL and upper active layers UAL are alternately stacked may be formed on the separation stack pattern DSP. The upper sacrificial layers USL and the upper active layers UAL may include the same material as the lower sacrificial layers BSL and the lower active layers BAL, respectively.

The stacked lower and upper sacrificial layers BSL and USL, lower and upper active layers BAL, UAL, and separation stack pattern DSP may be patterned to form a stack pattern SP. The step of forming the stack pattern SP may include a step of forming a hard mask pattern on the upper active layer UAL of the uppermost layer, and etching the stacked patterns BSL, BAL, USL, UAL, and DSP on the semiconductor substrate 101 by using the hard mask pattern as an etching mask.

While the stack pattern SP is formed, an upper portion of the semiconductor substrate 101 may be etched to form a trench. The trench may isolate the stack pattern SP into respective cells. As the trench is formed, a lower pattern BP disposed under the stack pattern SP of the semiconductor substrate 101 may be formed. The lower pattern BP may be formed by etching a part of the semiconductor substrate 101. The stack pattern SP and the lower pattern BP may have a bar shape or a line shape extending in the first direction D1.

The stack pattern SP may include the lower stack pattern BSP, the separation stack pattern DSP on the lower stack pattern BSP, and the upper stack pattern USP on the separation stack pattern DSP. The lower stack pattern BSP may include the lower sacrificial layers BSL and the lower active layers BAL which are alternately stacked. The upper stack pattern USP may include the upper sacrificial layers USL and the upper active layers UAL which are alternately stacked.

A field insulation film 105 filling between the lower patterns BP may be formed on the semiconductor substrate 101. The step of forming the field insulation film 105 may include forming an insulation film for covering the stack patterns SP on the entire surface of the semiconductor substrate 101, and recessing the insulation film until the sidewalls of the stack patterns SP are completely exposed. That is, the upper surface of the field insulation film 105 may be coplanar or substantially coplanar with the upper surface of the lower pattern BP.

Gate sacrificial patterns DSC crossing the stack pattern SP may be formed. The gate sacrificial patterns DSC may be formed on the stack pattern SP and the semiconductor substrate 101, and may have a line shape extending in the third direction D3. Specifically, forming the gate sacrificial patterns DSC may include a step of forming a sacrificial film on the entire surface of the semiconductor substrate 101, forming a hard mask pattern on the sacrificial film, and patterning the sacrificial film by using the hard mask pattern as an etching mask. The sacrificial film may include amorphous silicon and/or polysilicon. However, example embodiments are not limited thereto.

A first spacer film 171 may be conformally formed on the stack pattern STP, the gate sacrificial patterns DSC, the hard mask patterns DHM, and the field insulation film 105. Specifically, the first spacer film 171 may conformally cover the entire surface of the semiconductor substrate 101. For example, the first spacer film 171 may include at least one of SiCN, SiCON, and SiN. However, example embodiments are not limited thereto. The first spacer film 171 may cover a sidewall of the stack pattern SP and a sidewall of the gate sacrificial pattern DSC, and may cover an upper surface of the upper active layer UAL.

The step of forming the buried insulation pattern 110 may include covering the entire surfaces of the stack pattern SP and the semiconductor substrate 101, forming a preliminary buried insulation film filling between trenches, and performing a planarization process to partially expose the upper surface of the first spacer film 171. The preliminary buried insulation film may be coplanar or substantially coplanar with the uppermost end of the upper surface of the first spacer film 171.

The buried insulation pattern 110 may be formed by partially etching the preliminary buried insulation film. For example, the buried insulation pattern 110 may be formed through an etch back process. The first spacer film 171 may be disposed on the sidewall and the bottom surface of the buried insulation pattern 110. The upper surface of the buried insulation pattern 110 may be coplanar or substantially coplanar with the upper surface of the stack pattern SP. Accordingly, the buried insulation patterns 110 may be spaced apart from each other along the third direction D3 with the stack pattern SP interposed therebetween.

A second spacer film 172 may be formed on the buried insulation pattern 110 and the first spacer film 171. The second spacer film 172 may conformally cover the buried insulation pattern 110 and the first spacer film 171. For example, each of the second spacers SPC2 may include at least one of SiCN, SiCON, and SiN and a low-k material.

Referring to FIGS. 7A and 7B, an etching process may be performed on the stack pattern SP. The step of etching the stack pattern SP may include forming a mask pattern on the gate sacrificial pattern DSC and the hard mask pattern DHM, and etching the stack pattern SP by using the mask pattern as an etching mask.

By the etching process, a trench 150_T may be formed between the gate sacrificial patterns DSC adjacent to each other. As the trench 150_T is formed, the stack pattern SP may be formed in a vertical bar shape. The stack pattern SP may have a profile by etching. The sidewalls of the stack patterns SP may be inclined so as to become closer to each other toward the bottom. The trench 150_T may have a shape that becomes narrower toward the bottom.

The stack pattern SP may be patterned in the etching process, and a part of the buried insulation pattern 110 may remain. For example, the etching process may be performed through an etching recipe having a higher etch rate on silicon and silicon germanium. Specifically, the first and second spacer films 171, 172 covering the upper surface of the buried insulation pattern 110 may be removed, and in this process, the upper portion of the buried insulation pattern 110 may be etched together.

As a result, the buried insulation pattern 110 may have a rounded upper surface 110a. The buried insulation pattern 110 may have an upper surface forming a curved surface according to etching. The buried insulation pattern 110 may cover the field insulation film 105, and the field insulation film 105 may not be etched in the etching process.

A part of the first spacer film 171 conformally formed on the buried insulation pattern 110 may be removed by etching. The first spacer film 171 may be removed on the rounded upper surface 110a of the buried insulation pattern 110. A part of the first spacer film 171 may be removed on a side surface of the buried insulation pattern 110. Specifically, the first spacer film 171 may be removed at a position having a vertical level higher than the upper end of the separation stack pattern DSP, and may remain on a side surface of the buried insulation pattern 110 at a position having a vertical level lower than the upper end of the separation stack pattern DSP. However, example embodiments are not limited thereto, and the buried insulation pattern 110 may be etched in various shapes depending on a method and/or degree of etching the buried insulation pattern 110, and the pattern in which the first spacer film 171 remains may also vary.

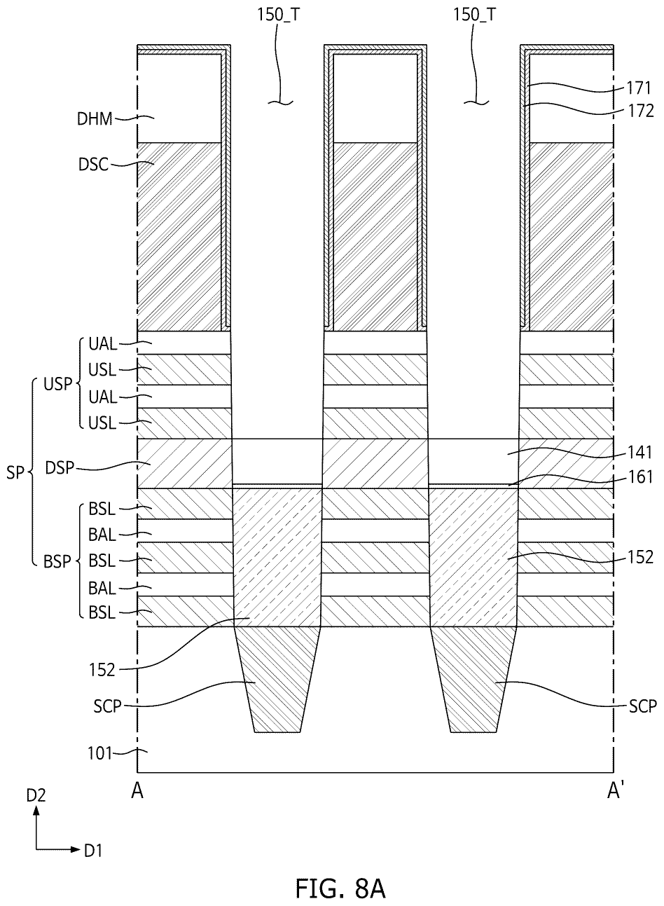

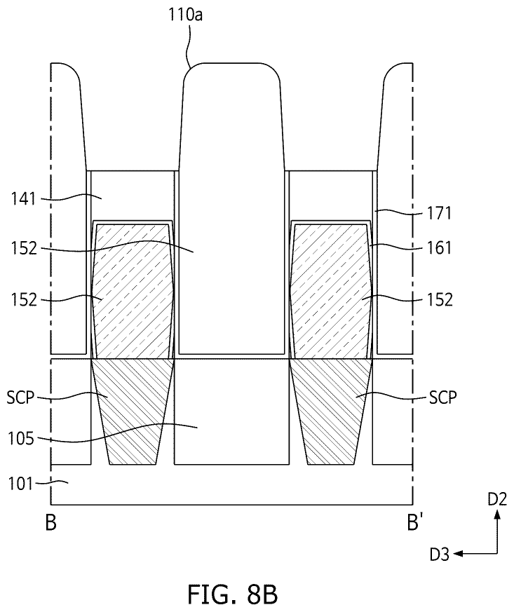

Referring to FIGS. 8A and 8B, sacrificial contact patterns SCP may be formed in the semiconductor substrate 101 exposed through the trench 150_T. The sacrificial contact patterns SCP may be arranged to be spaced apart from one another in the first direction D1. The sacrificial contact patterns SCP may include a material having an etch selectivity with the semiconductor substrate 101, for example, silicon-germanium (SiGe). However, example embodiments are not limited thereto. The sacrificial contact patterns SCP may be formed by an epitaxial growth process. The sacrificial contact pattern SCP may be formed within the trench 150_T.

A lower source/drain pattern 152 may be formed on the sacrificial contact pattern SCP within the trench 150_T. Specifically, the lower source/drain pattern 152 may be formed by performing a first selective epitaxial growth (SEG) process in which a sidewall of the lower stack pattern BSP exposed by the trench 150_T is used as a seed layer. The lower source/drain pattern 152 may be grown using lower active layers BAL exposed by a recess RS as a seed. For example, the first SEG process may include a chemical vapor deposition (CVD) process or a molecular beam epitaxy (MBE) process.

During the first SEG process, impurities may be injected in-situ into the lower source/drain pattern 152. In another example, after the lower source/drain pattern 152 is formed, impurities may be injected into the lower source/drain pattern 152. The lower source/drain pattern 152 may be doped to have a first conductivity (e.g., an N-type). The lower source/drain pattern 152 may be formed to completely fill a space between the lower active layers BAL adjacent to each other in the first direction D1.

The buried insulation pattern 110 may be disposed between the lower source/drain patterns 152 adjacent to each other in the third direction D3 (i.e., horizontally), and may suppress horizontal excessive growth of the lower source/drain pattern 152. For example, the lower source/drain patterns 152 may grow until they come into contact with the first spacer film 171, and, even if the lower source/drain patterns 152 grow for a sufficient time, the lower source/drain patterns 152 adjacent to each other in the third direction D3 may be horizontally spaced apart from each other due to the buried insulation pattern 110. That is, the buried insulation pattern 110 may control horizontal growth of the lower source/drain patterns 152 facing each other in the third direction D3.

In addition, the buried insulation pattern 110 may reduce or prevent a parasitic epitaxial pattern from being formed within the field insulation film 105. For example, if the buried insulation pattern 110 is not disposed, the field insulation film 105 may be partially etched in the process of forming a deeply formed trench 150_T (see FIG. 7B), and a parasitic epitaxial pattern may be formed within the field insulation film 105 through the etched portion. However, according to some examples of some example embodiments, the buried insulation pattern 110 having a sufficient height may be disposed on the field insulation film 105, and a parasitic epitaxial pattern may be reduced or prevented from being formed because the field insulation film 105 is not exposed in the process of forming the trench 150_T.

The first spacer film 171 may surround the bottom surface and the sidewalls of the buried insulation pattern 110. In other words, the first spacer film 171 may be interposed between the buried insulation pattern 110 and the lower source/drain pattern 152 to reduce or prevent oxidation of the lower source/drain pattern 152 during the growth process of the lower source/drain pattern 152. The first etching stop film 161 may cover the lower source/drain pattern 152 with a uniform or substantially uniform thickness.

The first interlayer insulation film 141 may be formed on the first etching stop film 161. The first interlayer insulation film 141 may be disposed on the lower source/drain pattern 152. The first interlayer insulation film 141 may cover an upper portion of the lower source/drain pattern 152.

In addition, the first spacer film 171 may be disposed on a side surface of the first interlayer insulation film 141. The first interlayer insulation film 141 may be disposed between the first spacer films 171.

The step of forming the first interlayer insulation film 141 may include filling the inside of the trench 150_T with an insulation film, partially removing the insulation film, and exposing a sidewall of the upper stack pattern USP in the trench 150_T again. That is, the first interlayer insulation film 141 may be disposed on the first etching stop film 161 and may expose the sidewall of the upper stack pattern USP. The first interlayer insulation film 141 may be positioned at the same level as the separation stack pattern DSP.

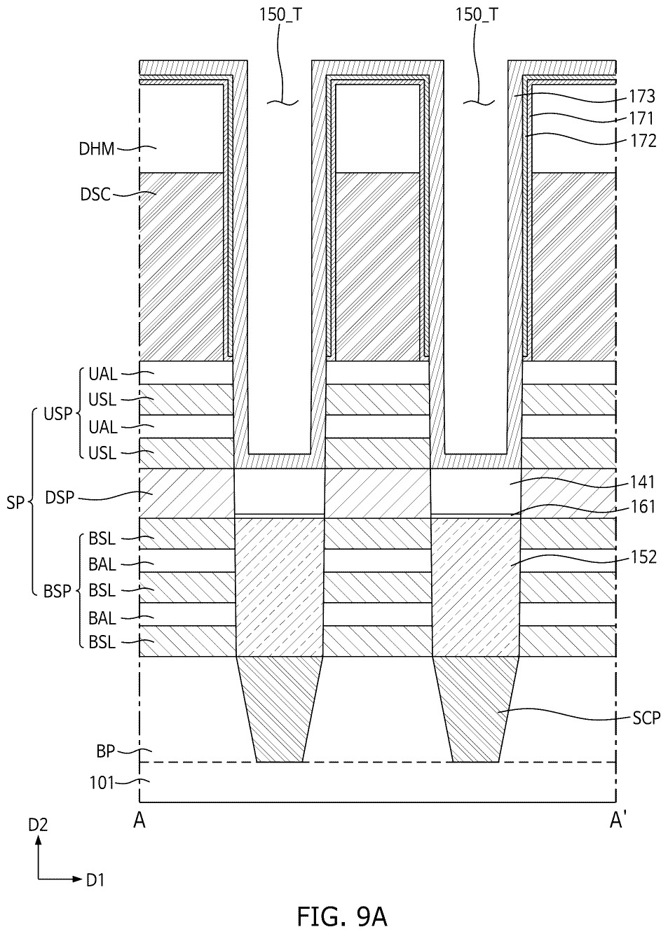

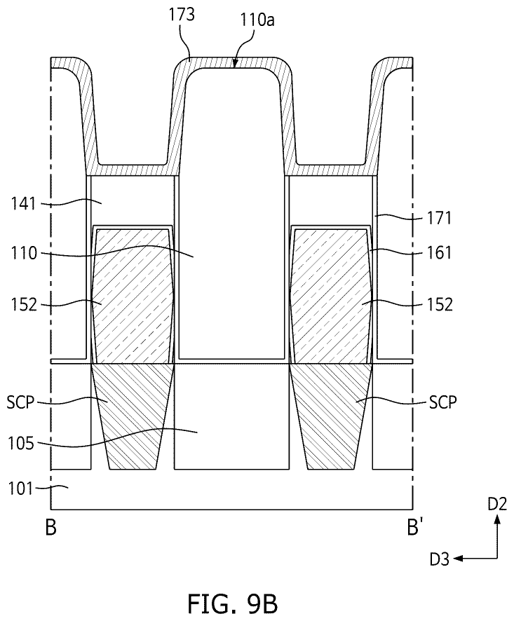

Referring to FIGS. 9A and 9B, a sacrificial liner 173 may be formed on the second spacer film 172, the upper stack pattern USP, the buried insulation pattern 110, and the first interlayer insulation film 141. The sacrificial liner 173 may conformally cover the second spacer film 172, the upper stack pattern USP, and the first interlayer insulation film 141. The sacrificial liner 173 may be formed by an atomic layer deposition (ALD) process or chemical vapor deposition (CVD). The sacrificial liner 173 may include a metal, a metal oxide, or a non-metallic material. For example, the sacrificial liner 173 may include molybdenum (Mo), SiCN, SiBCN, etc. However, example embodiments are not limited thereto, and the sacrificial liner 173 may include other materials having an etch selectivity with a peripheral configuration, such as a filler 200 and/or the buried insulation pattern 110, which will be described.

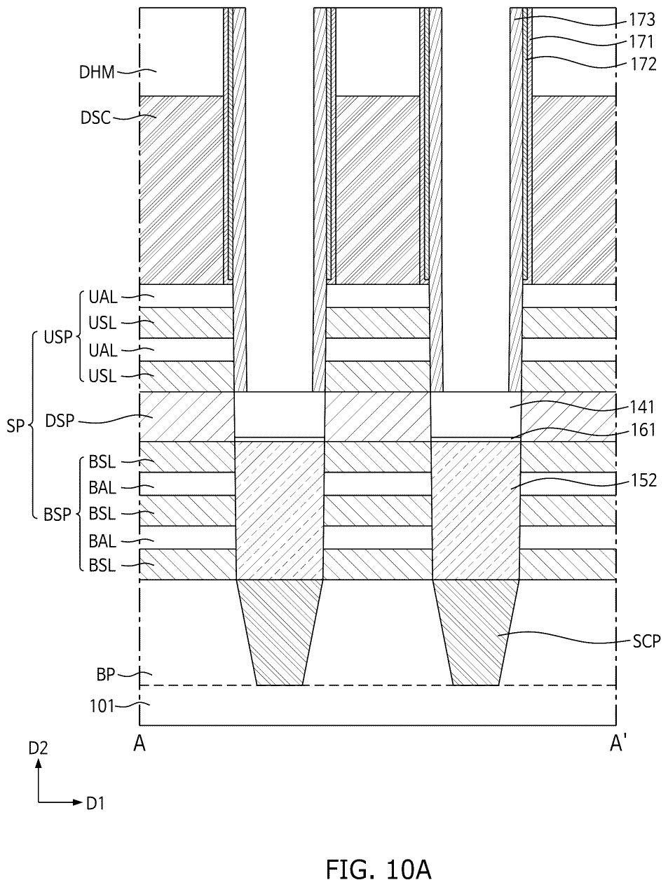

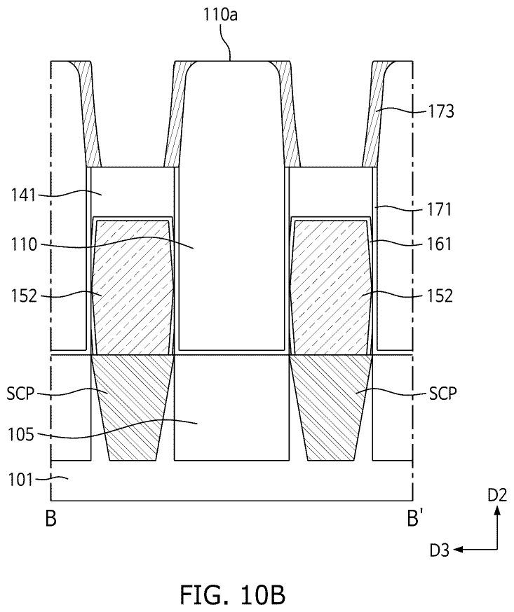

Referring to FIGS. 10A and 10B, an etching process may be performed on the sacrificial liner 173. The process of etching the sacrificial liner 173 may be performed by a dry etching process. Alternatively, the process of etching the sacrificial liner 173 may be performed by anisotropic etching. All portions of the sacrificial liner 173 that are parallel to the first and third directions D1 and D3 may be removed. Likewise, portions of the first and second spacer films 171 and 172 that are parallel to the first and third directions D1 and D3 may be removed. For example, a part of the first and second spacer films 171 and 172 may be removed so that the upper surfaces of the hard mask patterns DHM are exposed. In other words, the sacrificial liner 173 may remain on the sidewalls of the first and second spacer films 171 and 172, the sidewall of the upper stack pattern USP, and the upper surface of the first interlayer insulation film 141.

A part of the sacrificial liner 173, the first and second spacer films 171 and 172 may be removed to expose the hard mask patterns DHM in the second direction D2 (i.e., to expose upper portions). In addition, the sacrificial liner 173 may be removed to expose the buried insulation pattern 110 and the first interlayer insulation film 141 in the second direction D2 (that is, to expose upper portions).

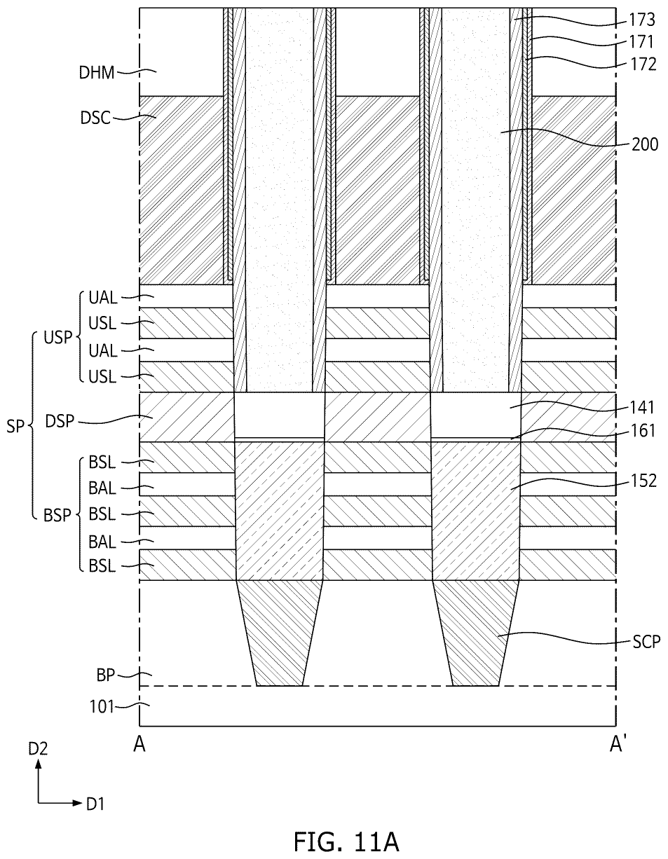

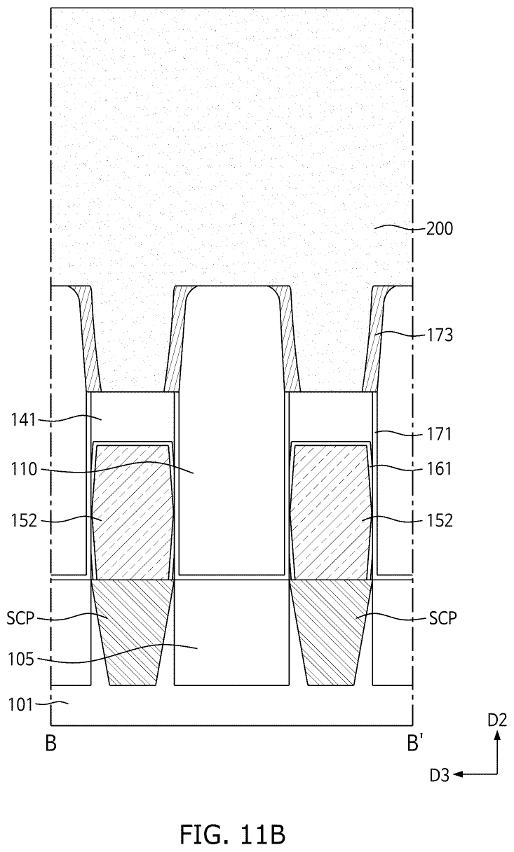

Referring to FIGS. 11A and 11B, a filler 200 may be filled in the trench 150_T (see FIG. 10A). The filler 200 may extend in the third direction D3. The filler 200 may cover the first interlayer insulation film 141, the sacrificial liner 173, and the buried insulation pattern 110. Specifically, the filler 200 may be filled between the sacrificial liners 173 in the inner space of the trench 150_T. In addition, the filler 200 may be disposed on the sacrificial liner 173 and the upper surface 110a of the buried insulation pattern 110. The filler 200 may include an insulation material. For example, the filler 200 may include a lanthanum (La) oxide, etc. However, the filler 200 is not limited thereto, and may include a material having an etch selectivity with a material (silicon (Si) or silicon germanium (SiGe), etc.) included in the sacrificial liner 173, the upper stack pattern USP, a silicon-based insulation material (a silicon oxide, a silicon oxynitride, a silicon nitride, etc.).

Referring to FIGS. 12A and 12B, the filler 200 may be recessed such that the height thereof may be reduced. Specifically, the upper surface of the filler 200 may be coplanar or substantially coplanar with the upper end of the upper stack pattern USP. As the filler 200 is recessed, the upper surface 110a of the buried insulation pattern 110 and a part of the sacrificial liner 173 may be exposed.

Referring to FIGS. 13A and 13B, the sacrificial liner 173 may be selectively etched. The process of etching the sacrificial liner 173 may be performed by wet etching. The process of etching the sacrificial liner 173 may be performed by isotropic etching. In this case, since the sacrificial liner 173 is formed of a material having an etch selectivity with a material included in peripheral components such as the filler, the upper stack pattern USP, only the sacrificial liner 173 may be etched.

After the sacrificial liner 173 is etched, an epitaxial growth space 151S may be formed between the filler 200 and the upper stack pattern USP. The epitaxial growth space 151S may be a space in which the upper source/drain pattern is grown.

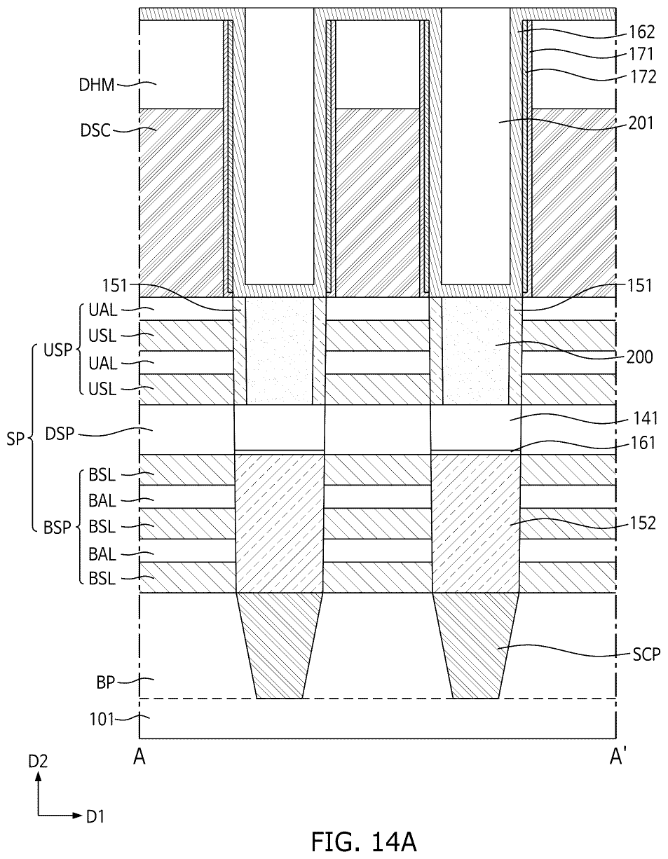

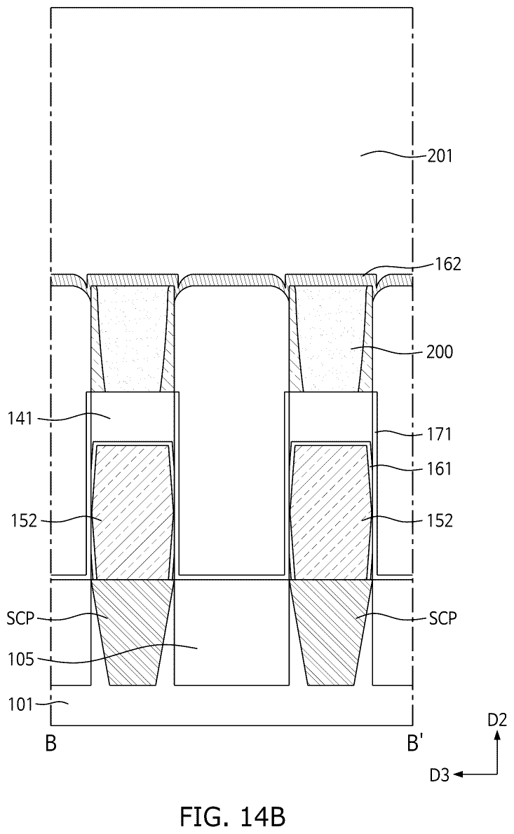

Referring to FIGS. 14A and 14B, the upper source/drain pattern 151 may be formed on an exposed sidewall of the upper stack pattern USP. Specifically, the upper source/drain pattern 151 may be formed by performing a second SEG process which uses the exposed sidewall of the upper stack pattern USP as a seed layer. The upper source/drain pattern 151 may be grown using the upper active layers UAL exposed by the epitaxial growth space 151S as a seed. The upper source/drain pattern 151 may be doped to have a second conductivity (e.g., a P-type) different from the first conductivity. The second SEG process may be performed for a time enough for the upper source/drain pattern 151 to sufficiently fill a space between the upper active layers UAL adjacent to each other in the first direction D1.

The buried insulation pattern 110 may be disposed between the upper source/drain patterns 151 adjacent to each other horizontally (that is, in the third direction D3), and may suppress horizontal excessive growth of the upper source/drain pattern 151. Specifically, the buried insulation pattern 110 may be disposed on at least one side of the upper source/drain pattern 151.

The upper source/drain pattern 151 may be grown using the exposed upper active layers UAL as a seed. The upper source/drain patterns 151 may be grown at positions spaced apart from each other, respectively. The upper source/drain patterns 151 may be structures that are isolated from each other. Specifically, the upper source/drain pattern 151 may grow until it comes into contact with the filler 200. That is, the upper source/drain pattern 151 may grow in the epitaxial growth space 150S. The upper end of the upper source/drain pattern 151 may be positioned at the same level or substantially the same level as the rounded upper surface 110a of the buried insulation pattern 110.

The second etching stop film 162 may be conformally formed on the upper source/drain pattern 151 and the filler 200. The second etching stop film 162 may cover the upper end of the upper source/drain pattern 151, the upper surface of the filler 200, and the rounded upper surface 110a of the buried insulation pattern 110 with a uniform or substantially uniform thickness. In addition, the second etching stop film 162 may cover the sidewalls of the first and second spacer films 171 and 172 and the upper surface of the hard mask pattern DHM.

An insulation film 201 may be formed on the second etching stop film 162. The insulation film 201 may be filled between the second etching stop films 162. The insulation film 201 may be coplanar or substantially coplanar with the uppermost end of the second etching stop film 162.

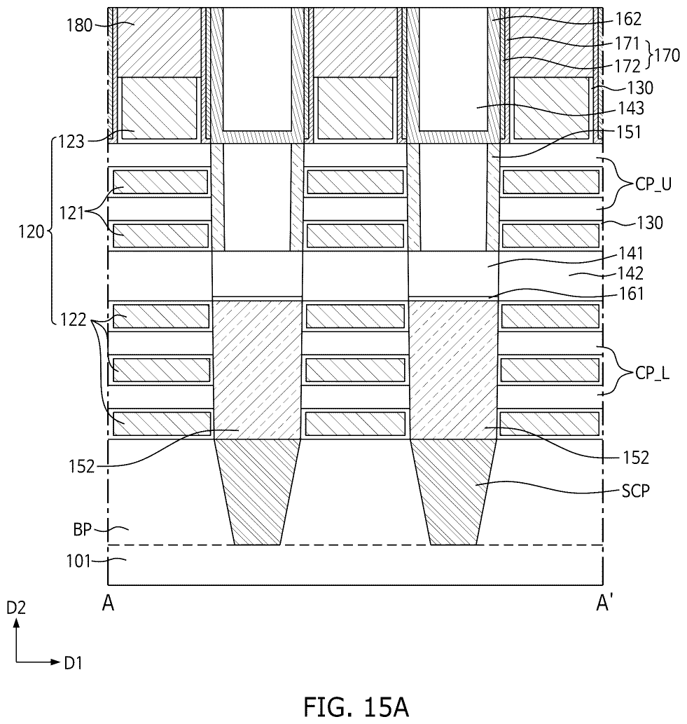

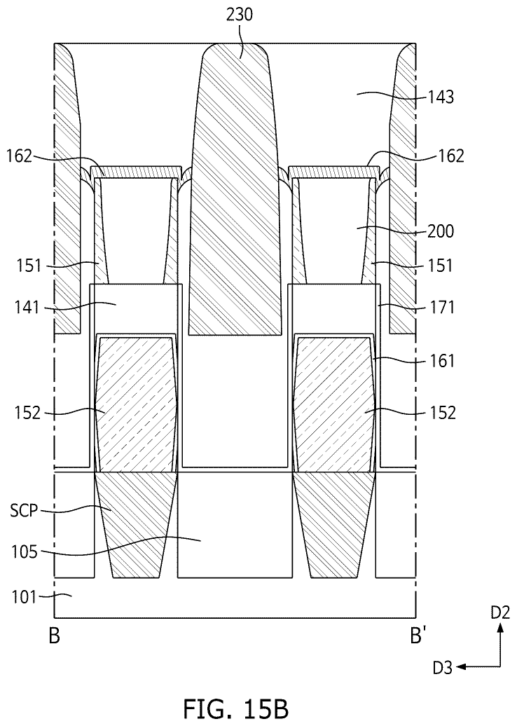

Referring to FIGS. 15A to 15B, a third interlayer insulation film 143 may be formed by recessing the insulation film 201 (see FIG. 14A). The third interlayer insulation film 143 filling the trench 150_T (see FIG. 9A) may be formed on the second etching stop film 162.

The step of forming the third interlayer insulation film 143 may include filling an insulation film on the second etching stop film 162 and performing a planarization process until the upper surface of the gate sacrificial pattern DSC is exposed. For example, the third interlayer insulation film 143 may include a silicon oxide film. The third interlayer insulation film 143 may be coplanar or substantially coplanar with the upper surface of the gate capping pattern 180, which will be described below, and may be spaced apart therefrom along the first direction D1.

The lower active layers BAL (see FIG. 14A) interposed between the lower source/drain patterns 152 may constitute a lower channel pattern CP_L. That is, the lower channel pattern CP_L may be formed from the lower active layers BAL.

The upper active layers UAL (see FIG. 14A) interposed between the upper source/drain patterns 151 may constitute an upper channel pattern CP_U. That is, the upper channel pattern CP_U may be formed from the upper active layers UAL.

The third interlayer insulation film 143 may be planarized until the upper surface of the gate sacrificial pattern DSC (see FIG. 14A) is exposed. The planarization of the third interlayer insulation film 143 may be performed by using an etch back or chemical mechanical polishing (CMP) process. During the planarization process, all the hard mask patterns MP on the gate sacrificial patterns DSC may be removed. A part of the first and second spacer films 171,172 protruding on the gate sacrificial pattern DSC may also be removed to form a gate spacer 170. The gate spacer 170 may cover the sidewall of the gate sacrificial pattern DSC and the uppermost end of the upper channel pattern CP_U.

The gate sacrificial pattern DSC may be selectively removed. The step of removing the gate sacrificial pattern DSC may include wet etching which uses an etching solution for selectively etching polysilicon. By removing the gate sacrificial pattern DSC, the upper and lower sacrificial layers USL and BSL (see FIG. 14A) may be exposed.

By performing the etching process of selectively etching the upper and lower sacrificial layers USL and BSL, only the upper and lower sacrificial layers USL, BSL except for the upper and lower channel patterns CP_U and CP_L and the separation stack pattern DSP may be removed. The etching process of selectively etching the upper and lower sacrificial layers USL and BSL may have a higher etch rate with respect to silicon germanium. For example, the etching process of selectively etching the upper and lower sacrificial layers USL and BSL may have a higher etch rate for silicon germanium having a germanium concentration greater than 10 at %.

The gate insulation film 130 may be conformally formed in a region from which the gate sacrificial pattern DSC and the upper and lower sacrificial layers USL and BSL are removed. The gate electrode 120 may be formed on the gate insulation film 130. The step of forming the gate electrode 120 may include forming the upper gate electrode 121 and the lower gate electrode 122 between the upper and lower channel patterns CP_U and CP_L, and forming the outer gate electrode 123 in a region from which the gate sacrificial pattern DSC is removed. The gate electrode 120 may be formed to surround the upper and lower channel patterns CP_U and CP_L.

A gate cut (not shown) may be further formed in the region from which the gate sacrificial pattern DSC is removed. The gate cut (not shown) may penetrate through the gate electrode 120 to penetrate through a part of the field insulation film 105.

The outer gate electrode 123 may be recessed such that its height may be reduced. The gate capping pattern 180 may be formed on the recessed outer gate electrode 123. A planarization process may be performed on the gate capping pattern 180 such that the upper surface of the gate capping pattern 180 is coplanar or substantially coplanar with the upper surface of the third interlayer insulation film 143. The gate capping pattern 180 may include at least one of SiON, SiCN, SiCON, and SiN. After the planarization process, a cleaning process may be additionally performed.

The contact insulation pattern 230 penetrating through the third interlayer insulation film 143 and the buried insulation pattern 110 may be formed. The step of forming the contact insulation pattern 230 may include forming a mask pattern, forming a through hole penetrating through the third interlayer insulation film 143 and the buried insulation pattern 110 by using the mask pattern as an etching mask, and filling the through hole with an insulation material. The contact insulation pattern 230 may include a silicon nitride (SiN), etc.

Referring to FIGS. 16A to 16C, an etching process of etching the third interlayer insulation film 143, the second etching stop film 162, and the filler 200 may be performed. The third interlayer insulation film 143 may be selectively etched. For example, the third interlayer insulation film 143 may be removed by a process of selectively etching a silicon oxide. The second etching stop film 162 may be removed by a process of selectively etching a silicon nitride. The process of etching the second etching stop film 162 may be performed by dry etching. Since the second etching stop film 162 is removed by etching having strong straightness, a surface parallel to the first and third directions D1 and D3 may be removed from the second etching stop film 162. While the second etching stop film 162 is etched, a part of the contact insulation pattern 230 may also be etched, such that the upper surface of the contact insulation pattern 230 may have a rounded shape.

The filler 200 may be a material having an etch selectivity with a material (silicon (Si), silicon germanium (SiGe), etc.) included in the upper channel pattern CP_U, and a material (silicon nitride (SiN), etc.) included in the second etching stop film. The process of etching the filler 200 may be performed by wet etching.

After the etching process is performed, the upper source/drain pattern 151, a part of the second etching stop film 162, the upper surface of the first interlayer insulation film 141, and the sidewall of the second etching stop film 162 may be exposed.

Referring to FIG. 16B, a first contact hole 241 may be formed in each of the first upper source/drain patterns 151_1. The first contact holes 241 may be formed at the same level as the upper source/drain pattern 151. The first contact holes 241 may be spaced apart from each other in the third direction D3. The second etching stop film 162 may remain between the first upper source/drain pattern 151_1 and the rounded upper surface 110a of the buried insulation pattern 110.

Referring to FIG. 16C, a second contact hole 242 may be formed in each of the second upper source/drain patterns 151_2. The second contact holes 242 may be formed at the same level as the second upper source/drain pattern 151_2. The second contact holes 242 may be spaced apart from each other in the third direction D3.

A through hole 250 penetrating through the first interlayer insulation film 141 and the first etching stop film 161 may be further formed. The step of forming the through hole 250 may include forming a mask pattern on the first contact hole 241, and forming the through hole 250 penetrating through the first interlayer insulation film 141 exposed through the second contact hole 242 and the first etching stop film 161 in the second direction D2. When the first interlayer insulation film 141 and the first etching stop film 161 are removed by the etching process, the upper surface of the second lower source/drain pattern 152_2 may be exposed through the through hole 250.

The through hole 250 may penetrate through a part of the second lower source/drain pattern 152_2. That is, a part of the upper surface of the second lower source/drain pattern 152_2 may be etched by the etching process.

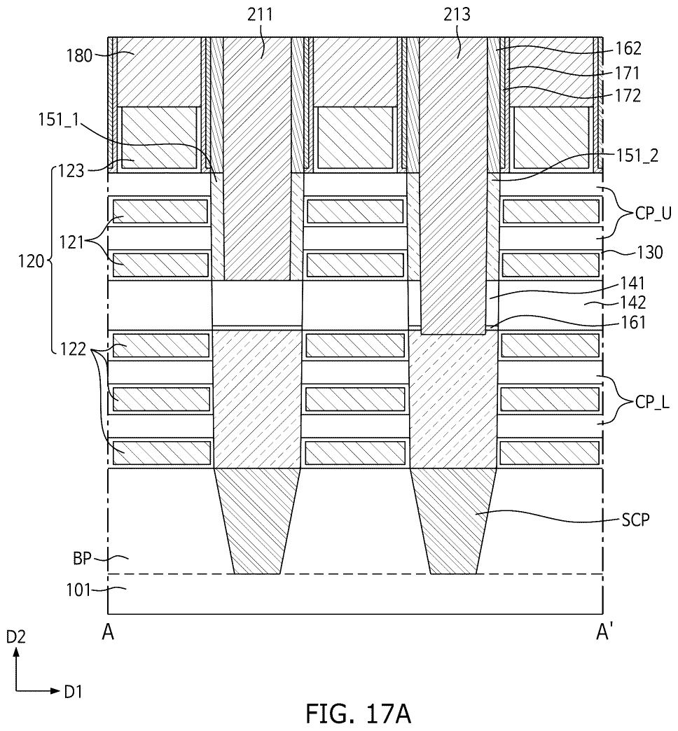

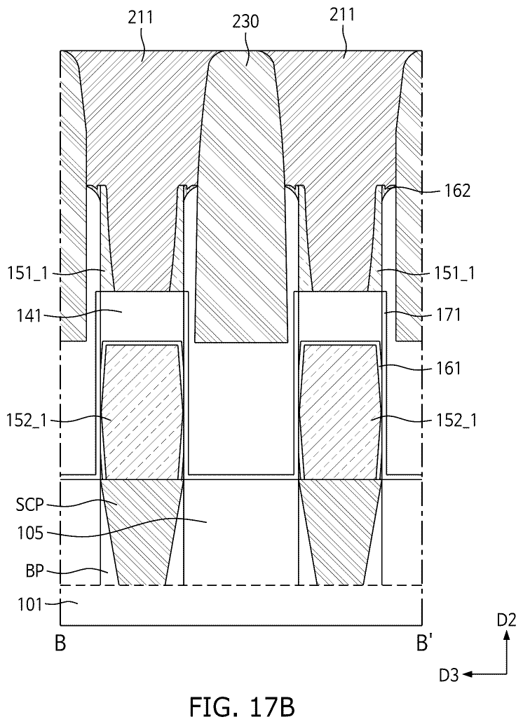

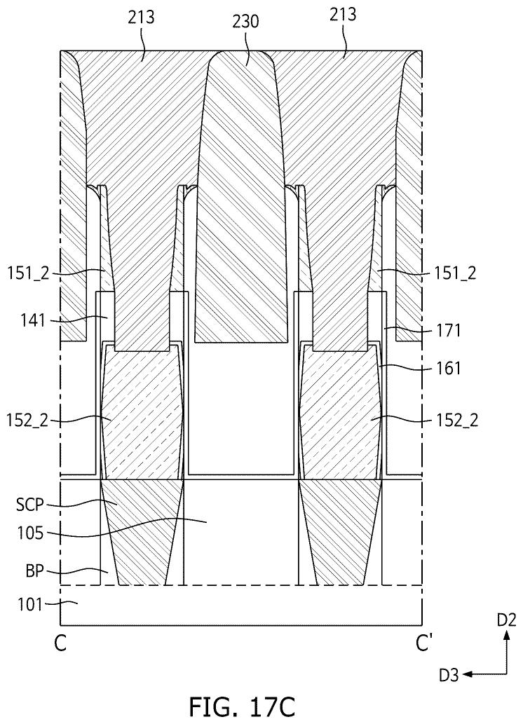

Referring to FIGS. 17A to 17C, the upper source/drain contact 211 may be formed in the first contact hole 241 (see FIG. 16B). The first contact hole 241 may be filled with a metallic material. The metallic material may include at least one of copper (Cu), aluminum (Al), ruthenium (Ru), cobalt (Co), tungsten (W), and molybdenum (Mo). However, example embodiments are not limited thereto.

The first upper source/drain contact 211 may be connected to the first upper source/drain pattern 151_1. The first upper source/drain contact 211 may be formed on the first upper source/drain pattern 151_1. The first upper source/drain contact 211 may be formed between the contact insulation patterns 230. The upper surface of the first upper source/drain contact 211 and the upper surface of the contact insulation pattern 230 may be coplanar or substantially coplanar.

The second upper source/drain contact 213 may be formed in the second contact hole 242 (see FIG. 16C) and the through hole 250 (see FIG. 16C). A metallic material may be filled between the through hole 250, the second contact hole 242, and the contact insulating patterns 230. The second upper source/drain contact 213 may cover the second lower source/drain pattern 152_2, the first interlayer insulation film 141, the second upper source/drain pattern 151_2, and the second etching stop film 162. The metallic material may include at least one of copper (Cu), aluminum (Al), ruthenium (Ru), cobalt (Co), tungsten (W), and molybdenum (Mo). However, example embodiments are not limited thereto.

The second upper source/drain contact 213 may be connected to the second upper source/drain pattern 151_2 and the second lower source/drain pattern 152_2, respectively. The second upper source/drain contact 213 may be formed between the first upper source/drain pattern 151_1 and the contact insulation pattern 230. The upper surface of the upper source/drain contact 211 and the upper surface of the contact insulation pattern 230 may be coplanar or substantially coplanar.

In a subsequent process, an upper wiring insulation film may be formed on the upper surfaces of the first and second upper source/drain contacts 211,213 and the upper surface of the contact insulation pattern 230. An upper wiring or the like forming an upper wiring structure may be formed inside the upper wiring insulation film. The upper wiring may include signal transmission wirings for connecting cells to each other.

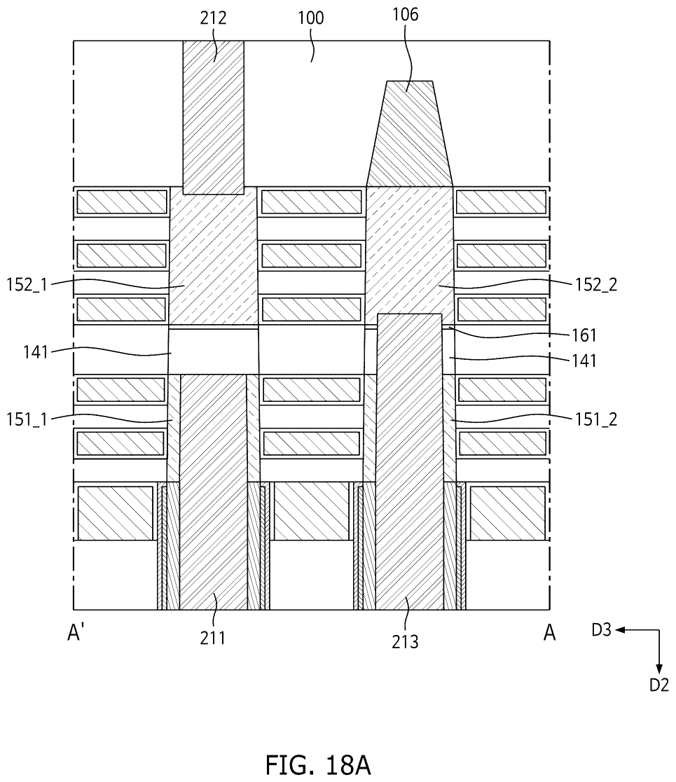

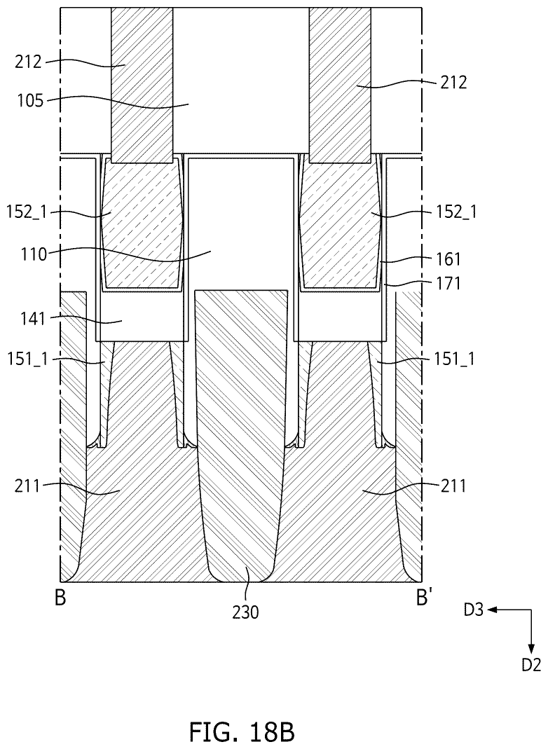

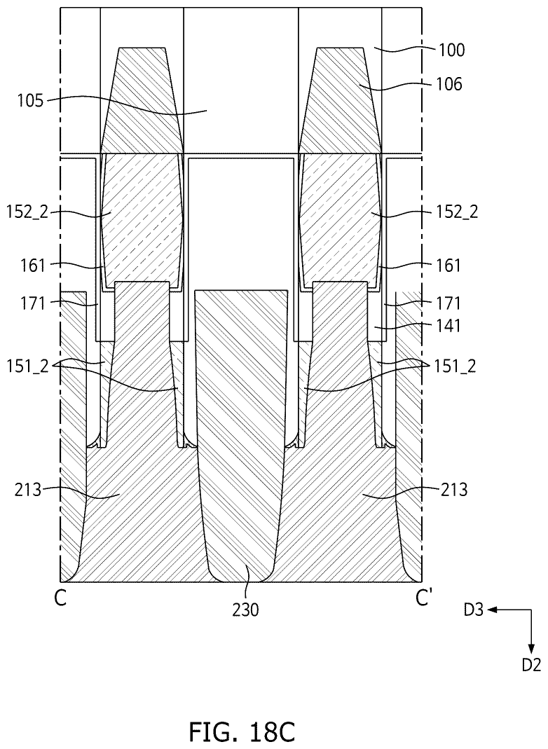

Referring to FIGS. 18A to 18C, the semiconductor substrate 101 may be inverted to have the rear surface of the semiconductor substrate 101 exposed. An etching process may be performed on the rear surface of the semiconductor substrate 101. A planarization process may be performed on the rear surface of the semiconductor substrate 101 until the upper surfaces of the sacrificial contact patterns SCP are exposed.

When the upper surfaces of the sacrificial contact patterns SCP are exposed, the sacrificial contact patterns SCP may be selectively removed. A region on the first lower source/drain pattern 152_1 among the regions from which the sacrificial contact patterns SCP are removed may be referred to as a first sacrificial contact pattern SCP_1, and a region on the second lower source/drain pattern 152_2 may be referred to as a second sacrificial contact pattern SCP_2.

The first sacrificial contact pattern SCP_1 may be replaced with the lower source/drain contact 212. The region from which the first sacrificial contact pattern SCP_1 is removed may be filled with a metallic material for forming the lower source/drain contact 212.

An etching process may be performed on the region from which the first sacrificial contact pattern SCP_1 is removed. The first lower source/drain pattern 152_1 may be exposed to the region from which the first sacrificial contact pattern SCP_1 is removed. The lower source/drain contact 212 connected to the exposed first lower source/drain pattern 152_1 may be formed. The lower source/drain contact 212 may be formed in a self-alignment manner using the sacrificial contact patterns SCP.

The second sacrificial contact pattern SCP_2 may be replaced with the lower insulation pattern 106. An insulation material may be filled on the region from which the second sacrificial contact pattern SCP_2 is removed.

The lower pattern BP and the semiconductor substrate 101 may be replaced with the substrate 100. The substrate 100 may partially fill a region from which the lower pattern BP is removed. The substrate 100 may be formed on the field insulation film 105. The substrate 100 may be disposed on a side surface of the field insulation film 105. The bottom surface of the substrate 100 may be coplanar or substantially coplanar with the bottom surface of the field insulation film 105. The substrate 100 may include a silicon-based insulation material (a silicon oxide, a silicon nitride, etc.). The substrate 100 may be formed under the first and second lower source/drain patterns 152_1 and 152_2 and the lower gate electrode 122. In another example, the semiconductor substrate 101 may not be removed.

In a subsequent process, a lower wiring insulation film may be formed under the field insulation film 105 and the bottom surface of the substrate 100. A lower wiring or the like forming a lower wiring structure may be formed inside the lower wiring insulation film. The lower wiring may include a power transmission network. The power transmission network may include a wiring network for applying a source voltage and a drain voltage to a rear metal layer.

According to some example embodiments of the present disclosure, a semiconductor device with improved integration density and/or electrical characteristics may be provided.

Some example embodiments of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

1. A semiconductor device, comprising:
a lower active pattern extending in a first direction and comprising a lower channel pattern;
an upper active pattern spaced apart from the lower active pattern in a second direction, the second direction intersecting the first direction, and the upper active pattern extending in the first direction, wherein the upper active pattern comprises an upper channel pattern;
a gate electrode surrounding the lower channel pattern and the upper channel pattern, and the gate electrode extending in a third direction, the third direction intersecting each of the first and second directions;
a lower source/drain pattern on at least one side of the lower channel pattern;
an upper source/drain pattern on at least one side of the upper channel pattern; and
an upper source/drain contact penetrating through the upper source/drain pattern in the second direction,
wherein the upper source/drain pattern comprises
a growth portion between the upper channel pattern and the upper source/drain contact, and the growth portion having a constant thickness along the third direction, and
an overgrowth portion protruding from the growth portion in the first direction.

2. The semiconductor device of claim 1, wherein a length of the overgrowth portion in the first direction increases toward an end of the growth portion in the third direction.

3. The semiconductor device of claim 1, wherein
a width of the upper channel pattern in the first direction increases toward the lower channel pattern, and
a width of the upper source/drain contact in the first direction decreases toward the lower source/drain pattern.

4. The semiconductor device of claim 1, wherein
the overgrowth portion has a width in the third direction, and
the width of the overgrowth portion in the third direction increases from an upper end of the upper source/drain pattern to a lower end of the upper source/drain pattern.

5. The semiconductor device of claim 1, further comprising a buried insulation pattern on at least one side of the upper source/drain pattern in the third direction, and
the buried insulation pattern comprising a rounded upper surface.

6. The semiconductor device of claim 5, further comprising an upper etching stop film between the buried insulation pattern and the upper source/drain pattern.

7. The semiconductor device of claim 6, wherein the upper etching stop film is on the rounded upper surface of the buried insulation pattern.

8. The semiconductor device of claim 7, wherein
the upper etching stop film comprises an indentation portion between the rounded upper surface of the buried insulation pattern and the upper source/drain pattern, and
at least a part of the upper source/drain contact fills the indentation portion.

9. The semiconductor device of claim 1, further comprising a lower source/drain contact contacting a lower portion of the lower source/drain pattern.

10. The semiconductor device of claim 1, further comprising a first interlayer insulation film between the upper source/drain pattern and the lower source/drain pattern,
wherein the upper source/drain contact penetrates through the first interlayer insulation film in the second direction to be in contact with an upper portion of the lower source/drain pattern.

11. The semiconductor device of claim 10, further comprising a lower insulation pattern on a lower portion of the upper source/drain pattern.

12. The semiconductor device of claim 1, further comprising a contact insulation pattern on at least one side of the upper source/drain contact.

13. The semiconductor device of claim 1, wherein the gate electrode comprises:
a lower gate electrode surrounding the lower channel pattern,
an upper gate electrode and an outer gate electrode, the upper gate electrode and the outer gate electrode surrounding the upper channel pattern, and
wherein the semiconductor device further comprises a second interlayer insulation film between the lower gate electrode and the upper gate electrode.

14. A semiconductor device, comprising:
a lower active pattern extending in a first direction and comprising a lower channel pattern;
an upper active pattern spaced apart from the lower active pattern in a second direction, the second direction intersecting the first direction, and the upper active pattern extending in the first direction, the upper active pattern comprising an upper channel pattern;
a gate electrode surrounding the lower channel pattern and the upper channel pattern, and the gate electrode extending in a third direction, the third direction intersecting each of the first and second directions;
a lower source/drain pattern on at least one side of the lower channel pattern;
an upper source/drain pattern on at least one side of the upper channel pattern;
a buried insulation pattern on at least one side of the upper source/drain pattern in the third direction, and the buried insulation pattern comprising a rounded upper surface;
an etching stop film between the buried insulation pattern and the upper source/drain pattern; and
an upper source/drain contact penetrating through the upper source/drain pattern in the second direction.

15. The semiconductor device of claim 14, wherein the upper source/drain pattern comprises:
a growth portion on the upper channel pattern, a thickness of the growth portion in the first direction is constant along the third direction; and
an overgrowth portion protruding from the growth portion in the first direction, and a length of the overgrowth portion protruding in the first direction increases toward an end of the growth portion in the third direction.

16. The semiconductor device of claim 14, wherein the etching stop film contacts an upper end of the upper source/drain pattern.

17. The semiconductor device of claim 16, further comprising a contact insulation pattern penetrating through an upper surface of the buried insulation pattern in the second direction and on at least one side of the upper source/drain contact in the third direction,
wherein the upper source/drain contact comprises
a first portion at a same vertical level as the upper source/drain pattern, and
a second portion at a higher vertical level than the upper source/drain pattern, and the second portion contacting the contact insulation pattern and the etching stop film.

18. The semiconductor device of claim 17, wherein the upper source/drain contact further comprises a third portion at a lower vertical level than the upper source/drain pattern, and the third portion contacting an upper portion of the lower source/drain pattern.

19. The semiconductor device of claim 18, wherein a width of the first portion in the third direction is greater than a width of the third portion in the third direction.

20. A semiconductor device comprising:
a lower active pattern extending in a first direction and comprising a lower channel pattern;
the lower active pattern comprising
a first lower source/drain pattern on a first side of the lower channel pattern, and
a second lower source/drain pattern on a second side of the lower channel pattern;
an upper active pattern comprising
an upper channel pattern spaced apart from the lower channel pattern in a second direction, the second direction intersecting the first direction,
a first upper source/drain pattern on a first side of the upper channel pattern, and
a second upper source/drain pattern on a second side of the upper channel pattern;
a first interlayer insulation film between the second upper source/drain pattern and the second lower source/drain pattern;
a gate electrode comprising
a lower gate electrode surrounding the lower channel pattern, and
an upper gate electrode and an outer gate electrode, the upper gate electrode and the outer gate electrode surrounding the upper channel pattern;
the gate electrode extending in a third direction, the third direction intersecting each of the first and second directions;
a second interlayer insulation film between the lower gate electrode and the upper gate electrode;
a buried insulation pattern between the first upper source/drain pattern and the second upper source/drain pattern, and the buried insulation pattern comprising a rounded upper surface;
a first etching stop film on the first lower source/drain pattern and the second lower source/drain pattern;
a second etching stop film on the rounded upper surface of the buried insulation pattern;
a first upper source/drain contact penetrating through the first upper source/drain pattern in the second direction; and
a second upper source/drain contact penetrating through the second upper source/drain pattern and the first interlayer insulation film in the second direction, and the second upper source/drain contact contacting an upper portion of the second lower source/drain pattern,
wherein each of the first upper source/drain pattern and the second upper source/drain pattern comprise
a growth portion having a constant thickness in the third direction,
an overgrowth portion protruding from the growth portion in the first direction, and
a length of the overgrowth portion that protrudes in the first direction increases toward an end of the growth portion in the third direction.
